(19) United States
(12) Patent Application Publication
(10) Pub. No.: US 2026/0101657 A1
(43) Pub. Date: Apr. 9, 2026

(54) DISPLAY PANEL AND MANUFACTURING METHOD THEREFOR, AND DISPLAY APPARATUS

(71) Applicant: BOE TECHNOLOGY GROUP CO., LTD., Beijing (CN)

(72) Inventors: Shu JING, Beijing (CN); Xiaobo DU, Beijing (CN); Songquan WU, Beijing (CN); Mingli LIU, Beijing (CN)

(21) Appl. No.: 19/109,708

(22) PCT Filed: Jan. 17, 2024
(86) PCT No.: PCT/CN2024/072667

§ 371 Date: Mar. 7, 2025

(30) Foreign Application Priority Data
Feb. 16, 2023 (CN) 202310172553.4

(51) Int. Cl. H10K 59/65; G06V 40/13; H10K 50/15; H10K 50/16; H10K 59/12; H10K 59/80; H10K 71/60

(52) U.S. Cl. CPC H10K 59/65; G06V 40/1318; H10K 50/156; H10K 50/166; H10K 59/1201; H10K 59/80518; H10K 59/80524; H10K 71/60

(57) ABSTRACT

The present disclosure relates to the technical field of light sensing, and provides a display panel and a manufacturing method therefor, and a display apparatus. The display panel comprises: a substrate; a driving layer, located at a side of the substrate and comprising a pixel circuit and a fingerprint recognition circuit that are spaced apart and insulated; and a light-emitting layer, located at a side of the driving layer away from the substrate, and comprising a light-emitting device and a light-sensing device that are spaced apart, the light-emitting device being connected to the pixel circuit, and the light-sensing device being connected to the fingerprint recognition circuit.

### CROSS REFERENCE

The present disclosure claims priority to Chinese Patent Application No. 202310172553.4, filed on Feb. 16, 2023, and entitled “DISPLAY PANEL AND MANUFACTURING METHOD THEREFOR, AND DISPLAY APPARATUS”, and the entire contents thereof are incorporated herein by reference.

### TECHNICAL FIELD

The present disclosure relates to the field of photosensitive technology, and in particular, to a display panel and a manufacturing method therefor, and a display apparatus.

### BACKGROUND

Photosensitive devices can convert light of different intensities into photocurrents of different magnitudes. Therefore, photosensitive elements are widely used in areas such as obtaining light intensity parameters and obtaining patterns through different light intensities, such as fingerprint recognition in display panels.

In fingerprint recognition applications, when a finger is placed above the photosensitive device in the fingerprint recognition element, the light emitted by the light source is incident on the valleys and ridges of the finger, and after reflection, is incident on the photosensitive device. Since the light intensities reflected from the valleys and ridges of the finger to the photosensitive device are different, the photocurrent generated by the photosensitive device is different, and the processor can then obtain the fingerprint pattern of the finger based on different photoelectric signals.

It should be noted that, information disclosed in the above background portion is provided only for better understanding of the background of the present disclosure, and thus it may contain information that does not form the prior art known by those ordinary skilled in the art

### SUMMARY

The present disclosure aims to provide a display panel and a manufacturing method thereof, and a display device.

In an aspect of the present disclosure, a display panel is provided, including:
a substrate;
a driving layer, disposed on a side of the substrate, and including a pixel circuit and a fingerprint recognition circuit that are spaced apart and insulated; and
a light-emitting layer, disposed on a side of the driving layer away from the substrate, and including a light-emitting device and a photosensitive device that are spaced apart, wherein the light-emitting device is connected to the pixel circuit, and the photosensitive device is connected to the fingerprint recognition circuit.

According to any of the display panel, the photosensitive device includes a first electron generating layer and a first hole generating layer; and
the light-emitting device includes a plurality of stacked light-emitting functional layers, and a second electron generating layer and a second hole generating layer located between two adjacent light-emitting functional layers, wherein one of the second electron generating layer is formed on a same layer as the first electron generating layer, and one of the second hole generating layer is formed on a same layer as the first hole generating layer.

According to any of the display panel, the first electron generating layer is disposed between the first hole generating layer and the substrate.

According to any of the display panel, the light-emitting device includes at least three light-emitting functional layers, and the first electron generating layer is disposed on a side of the first hole generating layer away from the substrate.

According to any of the display panel, the photosensitive device includes a first hole transport layer and/or a first electron transport layer, and the light-emitting functional layer of the light-emitting device includes a second hole transport layer and a second electron transport layer; and
wherein one of the second hole transport layer is formed on a same layer as the first hole transport layer, and one of the second electron transport layer is formed on a same layer as the first electron transport layer.

According to any of the display panel, the photosensitive device includes an anode modification layer and/or a cathode modification layer; and
wherein the anode modification layer is disposed on a side of the first hole generating layer away from the first electron generating layer, and the cathode modification layer is disposed on a side of the first electron generating layer away from the first hole generating layer.

According to any of the display panel, a material of the anode modification layer is: MoO3, WO3 or V2O5.

According to any of the display panel, the light-emitting device includes a first electrode and a second electrode, and the light sensing device includes a third electrode and a fourth electrode; and
wherein the first electrode is connected to the pixel circuit, the third electrode is connected to the fingerprint recognition circuit, and the first electrode and the third electrode are formed in a same layer.

According to any of the display panel, the first electrode includes a first transparent electrode, a first reflective electrode, and a second transparent electrode stacked in sequence in a direction away from the driving layer, and the third electrode is formed in a same layer as the first reflective electrode.

According to any of the display panel, the first electrode includes a first transparent electrode, a first reflective electrode, and a second transparent electrode sequentially stacked in a direction away from the driving layer; and
wherein the third electrode includes a third transparent electrode and a second reflective electrode which are sequentially stacked in a direction away from the driving layer, wherein the third transparent electrode is formed in a same layer as the first transparent electrode, and the second reflective electrode is formed in a same layer as the first reflective electrode.

According to any of the display panel, the second electrode and the fourth electrode are manufactured in a same layer.

According to any of the display panel, the fingerprint recognition circuit includes a thin film transistor, and a source or a drain of the thin film transistor is connected to the photosensitive device.

According to an aspect of the present disclosure, a method for manufacturing a display panel is provided, wherein the method includes:
providing a substrate;
forming a driving layer on a side of the substrate, wherein the driving layer includes a pixel circuit and a fingerprint recognition circuit that are spaced apart and insulated; and
forming a light-emitting layer on a side of the driving layer away from the substrate, wherein the light-emitting layer includes a light-emitting device and a photosensitive device that are spaced apart, wherein the light-emitting device is connected to the pixel circuit, and the photosensitive device is connected to the fingerprint recognition circuit,
wherein the photosensitive device includes a first electron generating layer and a first hole generating layer, the light-emitting device includes a plurality of stacked light-emitting functional layers, and a second electron generating layer and a second hole generating layer disposed between two adjacent light-emitting functional layers, one of the second electron generating layer is formed on a same layer as the first electron generating layer, and one of the second hole generating layer is formed on a same layer as the first hole generating layer.

According to any of the method, the forming the light-emitting layer on the side of the driving layer away from the substrate, includes:
forming a first electrode and a third electrode on a side of the driving layer away from the substrate, wherein the first electrode is an electrode of the light-emitting device, and the third electrode is an electrode of the photosensitive device;
evaporating a plurality of light-emitting functional layers on a side of the first electrode away from the substrate, with a second electron generating layer and a second hole generating layer sequentially stacked between two adjacent light-emitting functional layers, and meanwhile forming sequentially a first electron generating layer in a same layer as the second electron generating layer and a first hole generating layer in a same layer as the second hole generating layer on a side of the third electrode away from the substrate; and
forming a second electrode covering the plurality of light-emitting functional layers, and forming a fourth electrode covering the first hole generating layer, wherein the second electrode is another electrode of the light-emitting device, and the fourth electrode is another electrode of the photosensitive device.

According to any of the method, the forming the fourth electrode covering the first hole generating layer includes:
forming an anode modification layer on a side of the first hole generating layer away from the substrate; and
forming the fourth electrode on a side of the anode modification layer away from the substrate.

According to an aspect of the present disclosure, a display device is provided, wherein the display device includes the display panel of an aspect.

It is to be understood that both the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and together with the specification are used to explain the principles of the present disclosure. Obviously, the accompanying drawings described below are only some embodiments of the present disclosure, and for those skilled in the art, other accompanying drawings can be obtained based on these accompanying drawings without creative effort.

FIG. 1 is a schematic diagram of a partial cross-sectional structure of a display panel provided in an embodiment of the present disclosure.

FIG. 2 is a photoelectric performance graph of a single-layer and multi-layer light-emitting functional layer of a blue light-emitting device provided in an embodiment of the present disclosure.

FIG. 3 is a photoelectric performance graph of a single-layer and multi-layer light-emitting functional layer of a green light-emitting device provided in an embodiment of the present disclosure.

FIG. 4 is a photoelectric performance graph of a single-layer and multi-layer light-emitting functional layer of a red light-emitting device provided in an embodiment of the present disclosure.

FIG. 5 is a schematic diagram of a film structure of a light-emitting device provided in an embodiment of the present disclosure.

FIG. 6 is an energy level structure diagram of the light-emitting device shown in FIG. 5.

FIG. 7 is a schematic diagram of a partial cross-sectional structure of another display panel provided in an embodiment of the present disclosure.

FIG. 8 is a schematic diagram of a partial top view of a display panel provided in an embodiment of the present disclosure.

FIG. 9 is a graph showing electrical performance graphs of hole generation layers of various materials provided in an embodiment of the present disclosure.

FIG. 10 is a schematic diagram of a partial cross-sectional structure of another display panel provided in an embodiment of the present disclosure.

FIG. 11 is a schematic diagram of a partial cross-sectional structure of another display panel provided in an embodiment of the present disclosure.

FIG. 12 is a schematic diagram of a partial cross-sectional structure of another display panel provided in an embodiment of the present disclosure.

FIG. 13 is a schematic diagram of a film structure of a photosensitive device provided in an embodiment of the present disclosure.

FIG. 14 is an energy level structure diagram of the light-emitting device shown in FIG. 13.

FIG. 15 is a schematic flow chart of a method for manufacturing a display panel provided in an embodiment of the present disclosure.

FIG. 16 is a schematic diagram of the opening of the CFM when the light-emitting devices are arranged in an sRGB manner according to an embodiment of the present disclosure.

FIG. 17 is another schematic diagram of the opening of the CFM when the light-emitting devices are arranged in an sRGB manner according to an embodiment of the present disclosure.

FIG. 18 is another schematic diagram of the opening of the CFM when the light-emitting devices are arranged in an sRGB manner according to an embodiment of the present disclosure.

FIG. 19 is another schematic diagram of the opening of the CFM when the light-emitting devices are arranged in an sRGB manner according to an embodiment of the present disclosure.

FIG. 20 is a schematic diagram of the opening of the CFM when the light-emitting devices are arranged in a diamond pattern according to an embodiment of the present disclosure.

FIG. 21 is another schematic diagram of the opening of the CFM when the light-emitting devices are arranged in a diamond pattern according to an embodiment of the present disclosure.

FIG. 22 is another schematic diagram of the opening of the CFM when the light-emitting devices are arranged in a diamond pattern according to an embodiment of the present disclosure.

FIG. 23 is another schematic diagram of the opening of the CFM when the light-emitting devices are arranged in a diamond pattern according to an embodiment of the present disclosure.

FIG. 24 is a schematic diagram of the opening of the CFM when the light-emitting devices are arranged in a GGRB manner according to an embodiment of the present disclosure.

FIG. 25 is another schematic diagram of the opening of the CFM when the light-emitting devices are arranged in a GGRB manner according to an embodiment of the present disclosure.

FIG. 26 is a schematic diagram of the opening of the CFM when the light-emitting devices are arranged in a blue diamond manner according to an embodiment of the present disclosure.

FIG. 27 is another schematic diagram of the opening of the CFM when the light-emitting devices are arranged in a blue diamond manner according to an embodiment of the present disclosure.

FIG. 28 is another schematic diagram of the opening of the CFM when the light-emitting devices are arranged in a blue diamond manner according to an embodiment of the present disclosure.

FIG. 29 is another schematic diagram of the opening of the CFM when the light-emitting devices are arranged in a blue diamond manner according to an embodiment of the present disclosure.

FIG. 30 is another schematic diagram of the opening of the CFM when the light-emitting devices are arranged in a blue diamond manner according to an embodiment of the present disclosure.

FIG. 31 is another schematic diagram of the opening of the CFM when the light-emitting devices are arranged in a blue diamond manner according to an embodiment of the present disclosure.

FIG. 32 is another schematic diagram of the opening of the CFM when the light-emitting devices are arranged in a blue diamond manner according to an embodiment of the present disclosure.

FIG. 33 is another schematic diagram of the opening of the CFM when the light-emitting devices are arranged in a blue diamond manner according to an embodiment of the present disclosure.

### DETAILED DESCRIPTION

Example embodiments will now be described more fully with reference to the accompanying drawings. However, the example embodiments can be implemented in a variety of forms and should not be construed as limited to the embodiments set forth herein; rather, these embodiments are provided so that the present disclosure will be comprehensive and complete and fully convey the concepts of the example embodiments to those skilled in the art. The same reference numerals in the figures represent the same or similar structures, and thus their detailed description will be omitted. In addition, the drawings are only schematic illustrations of the present disclosure and are not necessarily drawn to scale.

Although relative terms such as “upper” and “lower” are used in this specification to describe the relative relationship of one component of the illustration to another component, these terms are used in this specification only for convenience, such as according to the orientation of the examples described in the drawings. It is understood that if the device of the illustration is turned upside down, the component described as “upper” will become the component “lower”. When a structure is “on” other structures, it may mean that the structure is formed integrally on the other structure, or that the structure is “directly” disposed on the other structure, or that the structure is “indirectly” disposed on the other structure through another structure.

The terms “a”, “an”, “the”, “said” and “at least one” are used to indicate the presence of one or more elements/components/etc. ; the terms “including” and “having” are used to express an open-ended inclusive meaning and mean that additional elements/components/etc. may exist in addition to the listed elements/components/etc.; the terms “first”, “second” and “third” etc. are used merely as labels and are not intended to limit the quantity of their objects.

A transistor is an element including at least three terminals: a gate electrode, a drain electrode, and a source electrode. A transistor has a channel region between the drain electrode (drain electrode terminal, drain region, or drain electrode) and the source electrode (source electrode terminal, source region, or source electrode), and current can flow through the drain electrode, the channel region, and the source electrode. The channel region refers to the region where current mainly flows.

The first electrode may be a drain electrode and the second electrode may be a source electrode, or the first electrode may be a source electrode and the second electrode may be a drain electrode. In the case of using transistors with opposite polarities or when the current direction changes during circuit operation, the functions of the “source electrode” and the “drain electrode” are sometimes interchanged. Therefore, in this specification, the “source electrode” and the “drain electrode” may be interchanged.

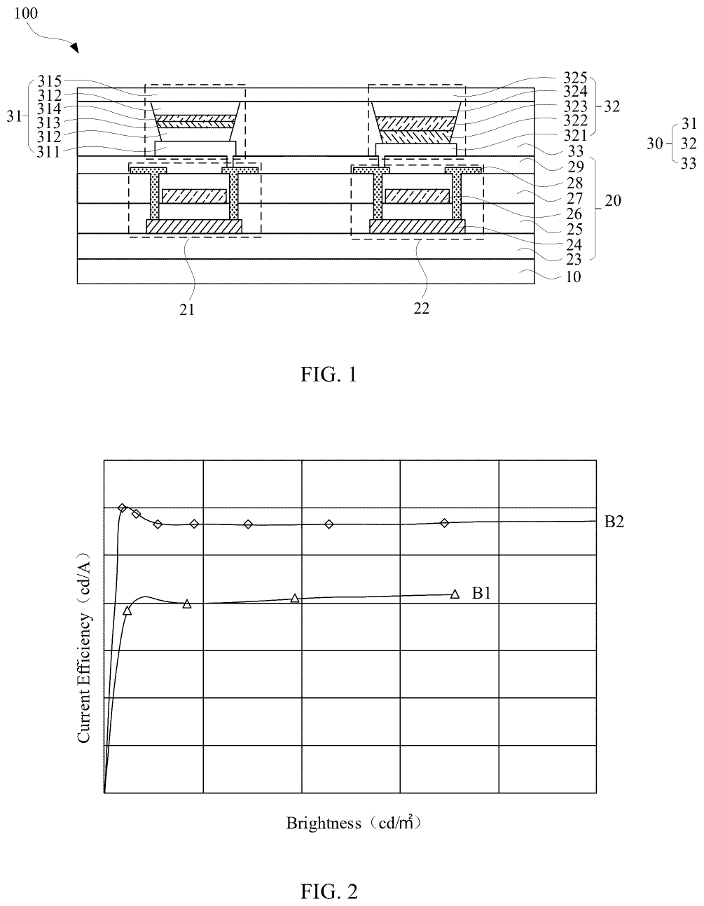

FIG. 1 illustrates a schematic diagram of a partial cross-sectional structure of a display panel 100 provided in an embodiment of the present disclosure. As shown in FIG. 1, the display panel 100 includes a substrate 10, a driving layer 20 and a light-emitting layer 30. The driving layer 20 is located on a side of the substrate 10 and includes a plurality of pixel circuits 21 distributed at intervals. The light-emitting layer 30 is located on the side of the driving layer 20 away from the substrate 10 and includes a plurality of light-emitting devices 31 distributed at intervals. A pixel circuit 21 is connected to at least one corresponding light-emitting device 31 (for example, a pixel circuit 21 is connected to a corresponding light-emitting device 31). In this way, the corresponding light-emitting device 31 can be driven to emit light by the pixel circuit 21 to realize the display of the picture.

In the implementation of the present disclosure, the material of the substrate 10 may be an inorganic material or an organic material. For example, in some embodiments, the material of the substrate 10 may be a glass material such as so-lime glass, quartz glass, sapphire glass, or a metal material such as stainless steel, aluminum, nickel, etc. In other embodiments, the material of the substrate 10 may be polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), polyethylene naphthalate (PEN), or a combination thereof.

The substrate 10 may be a single-layer structure or a composite of multiple layers. For example, the substrate 10 may be a composite of multiple layers, and the substrate 10 may include a first polyimide layer, a protective film layer, and a second polyimide layer stacked in sequence in a direction close to the driving layer 20.

In the implementation of the present disclosure, the pixel circuit 21 may include a plurality of transistors and pixel capacitors.

The transistor can be a thin film transistor, and the thin film transistor can be selected from a top-gate thin film transistor, a bottom-gate thin film transistor or a double-gate thin film transistor; the pixel capacitor can be a double-electrode capacitor or a triple-electrode capacitor. The material of the active layer 24 of the thin film transistor can be an amorphous silicon semiconductor material, a low-temperature polycrystalline silicon semiconductor material, a metal oxide semiconductor material, an organic semiconductor material or other types of semiconductor materials; the thin film transistor can be an N-type thin film transistor or a P-type thin film transistor.

It is understandable that, among the multiple transistors included in the pixel circuit 21, the types of any two transistors may be the same or different. Exemplarily, in some embodiments, some transistors in the pixel circuit 21 may be N-type transistors and some transistors may be P-type transistors. Again exemplarily, in other embodiments, the material of the active layer 24 of some transistors in the pixel circuit 21 may be a low-temperature polysilicon semiconductor material, and the material of the active layer 24 of some transistors may be a metal oxide semiconductor material.

In some embodiments, as shown in FIG. 1, the driving layer 20 includes a buffer layer 23, an active layer 24, a gate insulating layer 25, a gate metal layer 26, an interlayer insulating layer 27, a source-drain metal layer 28, and a planarizing layer 29 stacked in sequence in a direction away from the substrate 10.

The active layer 24 may be a polysilicon layer, an oxide film layer, or other structural layers, as long as it can form a channel region of the transistor and two connecting portions (with conductive properties) located on both sides of the channel region. The embodiments of the present disclosure do not limit this.

The gate metal layer 26 and the source-drain metal layer 28 may be a single-layer structure or a multi-layer structure. For example, the gate metal layer 26 includes a first gate metal layer 26 and a second gate metal layer 26, and/or the source-drain metal layer 28 includes a first source-drain metal layer 28 and a second source-drain metal layer 28. When the gate metal layer 26 is a multi-layer structure and the source-drain metal layer 28 is a multi-layer structure, the number of layers of the gate insulating layer 25 and the planarizing layer 29 will be adjusted accordingly, and the present disclosure does not limit this.

The planar layer 29 is provided with a via hole, and a pixel circuit 21 is connected to at least one light-emitting device 31 through the via hole in the planar layer 29.

In the embodiment of the present disclosure, the plurality of light-emitting devices 31 of the light-emitting layer 30 may be classified into a plurality of light-emitting units, and the plurality of light-emitting units are distributed in an array. Each light-emitting unit includes a plurality of light-emitting devices 31 with different light-emitting colors. For example, a light-emitting unit may include a red light-emitting device 31 emitting red light, a green light-emitting device 31 emitting green light, and a blue light-emitting device 31 emitting blue light; or a light-emitting unit may include a red light-emitting device 31 emitting red light, a green light-emitting device 31 emitting green light, a blue light-emitting device 31 emitting blue light, and a white light-emitting device 31 emitting white light.

In some embodiments, the light-emitting device 31 is an organic light-emitting diode (OLED), as shown in FIG. 1, which includes a first electrode 311, a light-emitting functional layer 312, and a second electrode 315 sequentially stacked in a direction away from the substrate 10.

The first electrode 311 can be arranged on the side of the driving layer 20 away from the substrate 10, and connected to the corresponding pixel circuit 21, and the first electrode 311 can be a single-layer structure or a composite of a multi-layer structure. For example, when the first electrode 311 is a single-layer structure, the first electrode 311 can include a transparent electrode ITO layer; when the first electrode 311 is a composite of a multi-layer structure, the first electrode 311 includes a first transparent electrode ITO layer, a reflective electrode Ag layer, and a second transparent electrode ITO layer stacked in sequence along the side away from the driving layer 20. The second electrode 315 covers the light-emitting functional layer 312, and the second electrodes 315 of multiple light-emitting devices 31 can share an electrode layer. The second electrode 315 can be a single-layer structure or a composite of a multi-layer structure. For example, when the second electrode 315 is a single-layer structure, the second electrode 315 can be a MgAg composite material layer.

As shown in FIG. 1, a plurality of light-emitting functional layers 312 are stacked between the first electrode 311 and the second electrode 315, and a second charge generating layer is provided between two adjacent light-emitting functional layers 312. The second charge generating layer includes a second electron generating layer 313 and a second hole generating layer 314. The second electron generating layer 313 is located on the side close to the first electrode 311 to cooperate with the first electrode 311 or the second hole generating layer 314 adjacent to the lower layer to realize light-emitting of the light-emitting functional layer 312; the second hole generating layer 314 is located on the side away from the first electrode 311 to cooperate with the second electrode 315 or the second electron generating layer 313 adjacent to the upper layer to realize light-emitting of the light-emitting functional layer 312.

Optionally, the material of the second electron generating layer 313 is: C60, etc., and the material of the second hole generating layer 314 is: m-MTDATA, CuPc, Pentance, TCTA, CBP, TPD, 2-NTANA, NPB, SubPc, etc.

The light-emitting colors of the multiple light-emitting functional layers 312 of each light-emitting device 31 are the same, that is, the light emitted by each light-emitting device 31 is monochromatic light; or there are two light-emitting functional layers 312 with different light-emitting colors among the multiple light-emitting functional layers 312 of each light-emitting device 31, that is, the light emitted by each light-emitting device 31 is mixed color light. For example, when the light-emitting device 31 includes three light-emitting functional layers 312 of red, blue and green, the light emitted by the light-emitting device 31 is white light. When the light emitted by the light-emitting device 31 is white light, in order to display a color picture, the display panel 100 includes a color filter layer located on the side of the light-emitting layer 30 away from the substrate 10.

The light-emitting functional layer 312 at least includes a composite light-emitting layer EML. Taking the first electrode 311 as an anode and the second electrode 315 as a cathode as an example, holes can be transmitted to the composite light-emitting layer EML through the first electrode 311 or the second hole generation layer 314, and electrons can be transmitted to the composite light-emitting layer EML through the second electrode 315 or the second electron generation layer 313, and then the composite light-emitting layer EML realizes light emission through the recombination of holes and electrons, and the color of the light emission depends on the material of the composite light-emitting layer EML. In order to improve the transmission effect of holes and electrons and improve the light-emitting effect of the composite light-emitting layer EML, the side of the composite light-emitting layer EML close to the first electrode 311 has at least one of a hole injection layer HIL, a hole transport layer HTL, and an electron blocking layer EBL, and the side of the composite light-emitting layer EML close to the second electrode 315 has at least one of a hole blocking layer HBL, an electron transport layer ETL, and an electron injection layer EIL.

Optionally, the material of the hole injection layer HIL is: organic small molecule materials with hole injection performance such as HATCN, F4-TCNQ, TCNQ. The material of the hole transport layer HTL is: organic small molecule materials with hole transport performance such as NPB, NPD, TAPC. The material of the electron transport layer ETL is: organic small molecule materials with electron transport performance such as Alq3, Bphen, BCP, TPBi. The material of the electron injection layer EIL is: metal or metal oxide materials with electron injection performance such as Yb, Li, Liq, CsCO3. The material of the blue light composite emitting layer EML is: all OLED blue emitting materials, including blue fluorescent emitting body, blue fluorescent emitting dye, blue phosphorescent emitting body, blue phosphorescent emitting dye, non-doped blue emitting material and blue light quantum dots, etc. The material of the green light composite emitting layer EML is: all OLED green emitting materials, including green fluorescent emitting body, green fluorescent emitting dye, green phosphorescent emitting body, green phosphorescent emitting dye, non-doped green emitting material and green light quantum dots, etc. The material of the red light composite emitting layer EML is: all OLED red light-emitting materials, including red fluorescent light-emitting body, red fluorescent light-emitting dye, red phosphorescent light-emitting body, red phosphorescent light-emitting dye, non-doped red light-emitting material and red light quantum dots, etc.

Taking the three light-emitting devices 31 of blue, green and red as examples, the photoelectric performances are compared in combination with a single-layer light-emitting functional layer 312 and a multi-layer light-emitting functional layer 312 respectively.

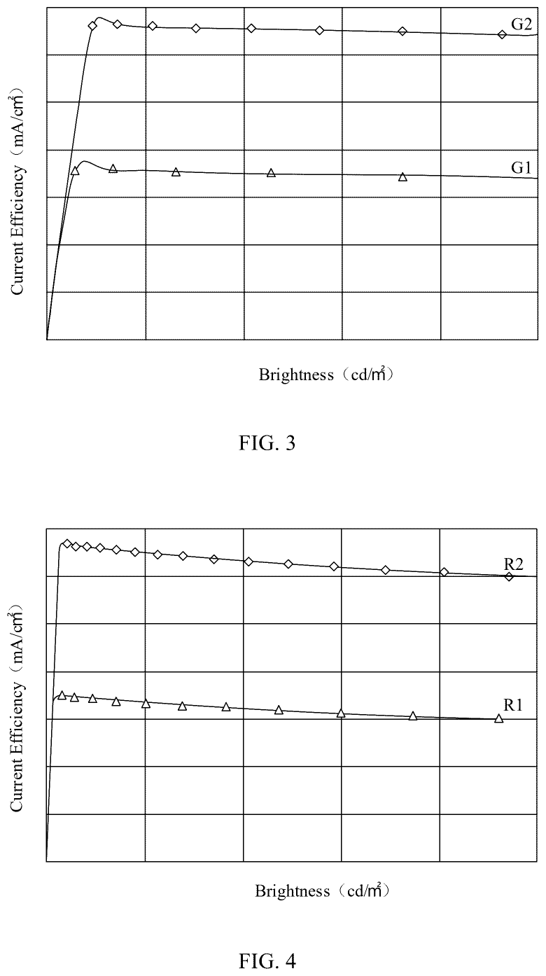

As shown in FIG. 2, the photoelectric performance graph B1 when the blue light-emitting device 31 has a single-layer light-emitting functional layer 312, and the photoelectric performance graph B2 when the blue light-emitting device 31 has a multi-layer light-emitting functional layer 312 are shown; as shown in FIG. 3, the photoelectric performance graph G1 when the green light-emitting device 31 has a single-layer light-emitting functional layer 312, and the photoelectric performance graph G2 when the green light-emitting device 31 has a multi-layer light-emitting functional layer 312 are shown; as shown in FIG. 4, the photoelectric performance graph R1 when the red light-emitting device 31 has a single-layer light-emitting functional layer 312, and the photoelectric performance graph R2 when the red light-emitting device 31 has a multi-layer light-emitting functional layer 312 are shown.

In FIGS. 2, 3 and 4, the horizontal axis is brightness (i.e., luminous intensity per unit area), and the vertical axis is current efficiency (i.e., luminous intensity per unit current). It can be seen from FIGS. 2, 3 and 4 that the photoelectric performance of the light-emitting device 31 when it is a single-layer light-emitting functional layer 312 is significantly weaker than the photoelectric performance of the light-emitting device 31 when it is a multi-layer light-emitting functional layer 312. Therefore, the light-emitting effect of the display panel 100 can be more effectively improved by using a multi-layer light-emitting functional layer 312 for the light-emitting device 31.

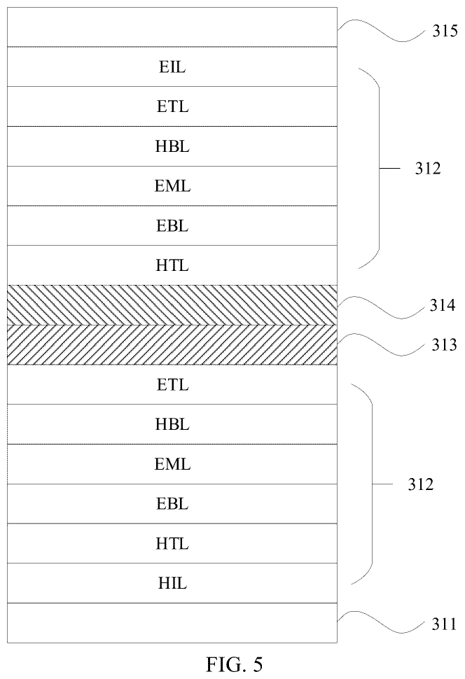

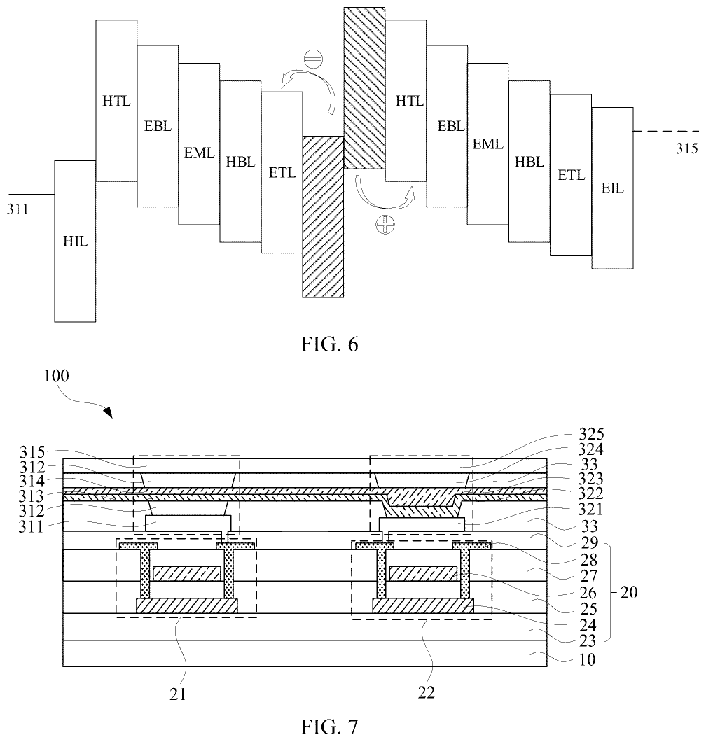

It should be noted that, in the case where the light-emitting device 31 includes a plurality of light-emitting functional layers 312, the film structure included in each light-emitting functional layer 312 may be different or the same. Taking the light-emitting device 31 including two light-emitting functional layers 312 as an example, as shown in FIG. 5, in the lower light-emitting functional layer 312 (i.e., a light-emitting functional layer 312 close to the first electrode 311), the side of the composite light-emitting layer EML close to the first electrode 311 has a hole injection layer HIL, a hole transport layer HTL, and an electron blocking layer EBL, and the side of the composite light-emitting layer EML close to the second electrode 315 has a hole blocking layer HBL and an electron transport layer ETL; in the upper light-emitting functional layer 312 (i.e., a light-emitting functional layer 312 close to the second electrode 315), the side of the composite light-emitting layer EML close to the first electrode 311 has a hole transport layer HTL and an electron blocking layer EBL, and the side of the composite light-emitting layer EML close to the second electrode 315 has a hole blocking layer HBL, an electron transport layer ETL, and an electron injection layer EIL. Correspondingly, the energy level structure diagram of the light-emitting device 31 is shown in FIG. 6.

In the embodiment of the present disclosure, as shown in FIG. 1, the light-emitting layer 30 includes a pixel definition layer 33, which is located on the side of the first electrode 311 away from the substrate 10 and is provided with pixel openings with one-to-one correspondence to a plurality of light-emitting devices 31. The first electrode 311 includes an exposed area exposed at the corresponding pixel opening and a covered area covered by the pixel definition layer 33. The exposed area of the first electrode 311 forms a light-emitting area of the corresponding light-emitting device 31.

In combination with the above case that the light-emitting device 31 includes multiple light-emitting functional layers 312, the pixel definition layer 33 can be a whole layer structure, and the charge generation layer is a patterned structure, so that as shown in FIG. 1, the multiple light-emitting functional layers 312 included in the light-emitting device 31 and the charge generation layer between two adjacent light-emitting functional layers 312 are all located in the corresponding pixel openings; or as shown in FIG. 7, the pixel definition layer 33 is a multi-layer structure, and at this time, the multiple pixel definition layers 33 correspond one-to-one to the multiple light-emitting functional layers 312, and there is a charge generation layer between every two adjacent pixel definition layers 33, and each pixel definition layer 33 has pixel openings corresponding one-to-one to the multiple light-emitting devices 31, so that each light-emitting functional layer 312 included in the light-emitting device 31 is located in the pixel opening on the corresponding pixel definition layer 33.

In some embodiments, the display panel 100 further includes a functional layer, such as a thin film encapsulation layer, a touch function layer, etc.

Taking the display panel 100 including a thin film encapsulation layer as an example, the thin film encapsulation layer is located on the side of the light-emitting layer 30 away from the substrate 10 to cover the light-emitting device 31 included in the light-emitting layer 30, thereby protecting the light-emitting device 31 to prevent external moisture and oxygen from corroding the light-emitting device 31.

The thin film encapsulation layer may include an inorganic encapsulation layer and an organic encapsulation layer that are alternately stacked. The inorganic encapsulation layer can effectively block external moisture and oxygen, preventing water and oxygen from penetration into the organic light-emitting functional layer 312 and causing material degradation; the organic encapsulation layer is located between two adjacent inorganic encapsulation layers to achieve flattening and reduce stress between the inorganic encapsulation layers.

The display panel 100 has a display area 101 and a peripheral area located outside the display area 101, the edge of the inorganic encapsulation layer can be located in the peripheral area, and the edge of the organic encapsulation layer can be located between the edge of the display area 101 and the edge of the inorganic encapsulation layer. Exemplarily, the thin film encapsulation layer includes a first inorganic encapsulation layer, an organic encapsulation layer, and a second inorganic encapsulation layer sequentially stacked on the side of the light-emitting layer 30 away from the substrate 10.

Taking the display panel 100 including a touch function layer as an example, the touch function layer is located on a side of the thin film encapsulation layer away from the substrate 10 to implement a touch operation on the display panel 100.

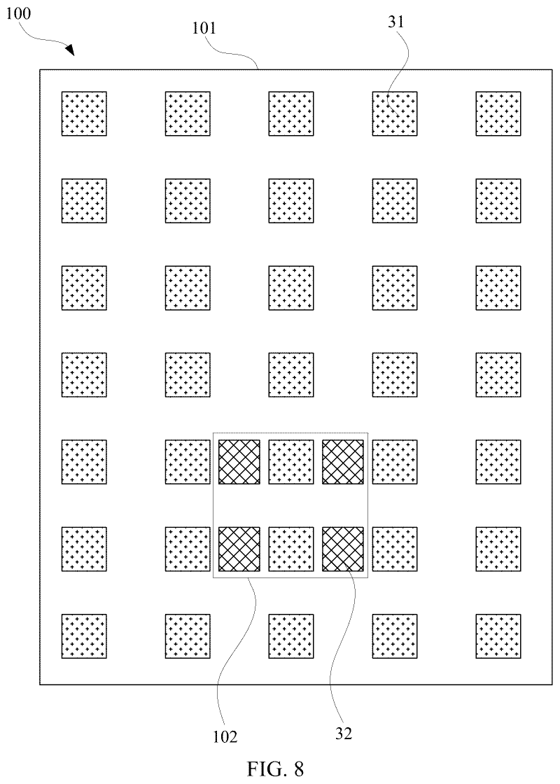

FIG. 8 illustrates a schematic diagram of a top view structure of a display panel 100 provided in an embodiment of the present disclosure. As shown in FIG. 8, the display panel 100 includes: a display area 101 and a fingerprint recognition area 102. The display area 101 has a plurality of light-emitting devices 31 distributed in an array, so as to realize the display of the image through the light emission of the plurality of light-emitting devices 31; the fingerprint recognition area 102 has a plurality of photosensitive devices 32 distributed in an array, so as to realize the collection of the fingerprint of the finger by the finger-reflected-light collected by the plurality of photosensitive devices 32. In this way, by combining the light-emitting devices 31 and the photosensitive devices 32, the function of displaying the picture and the function of fingerprint recognition of the display panel 100 can be realized.

As shown in FIG. 8, the fingerprint recognition area 102 is located in the display area 101, so that the area where the fingerprint recognition area 102 is located has both fingerprint recognition and image display functions, thereby avoiding the appearance of local dark areas on the display panel 100 and affecting the full-screen effect of the display panel 100.

For example, multiple photosensitive devices 32 and some of the light-emitting devices 31 among the multiple light-emitting devices 31 are spaced apart along the length and width directions of the display panel 100, that is, the area where the fingerprint recognition area 102 (partial area within the display area 101) is located has both light-emitting devices 31 and photosensitive devices 32, and a photosensitive device 32 is provided between two adjacent light-emitting devices 31 in the length and width directions of the display panel 100.

In order to realize the fingerprint recognition function of the display panel 100, combined with the above-mentioned film structure of the display panel 100, in the related art, the photosensitive device 32 is arranged on the back side of the display panel 100, that is, the side of the substrate 10 away from the driving layer 20. At this time, when performing fingerprint recognition, the distance between the photosensitive device 32 and the finger is the overall thickness of the display panel 100. In this way, the distance between the photosensitive device 32 and the finger is large, so that the fingerprint recognition efficiency is low.

In the present application, the photosensitive device 32 is arranged in the light-emitting layer 30, that is, as shown in FIG. 1 or FIG. 7, the driving layer 20 includes a fingerprint recognition circuit 22 spaced apart and insulated from the pixel circuit 21, and the light-emitting layer 30 includes a photosensitive device 32 spaced apart from the light-emitting device 31, and the photosensitive device 32 is connected to the fingerprint recognition circuit 22. In this way, by arranging the photosensitive device 32 in the light-emitting layer 30, the distance between the photosensitive device 32 and the finger during fingerprint recognition is shortened to the maximum extent, thereby effectively improving the recognition efficiency of the fingerprint.

In combination with the above case that the light-emitting layer 30 includes the pixel definition layer 33, the pixel definition layer 33 is provided with a photosensitive opening corresponding to the photosensitive device 32, and the photosensitive device 32 is arranged in the corresponding photosensitive opening on the pixel definition layer 33. The relative position of the pixel opening and the photosensitive opening on the pixel definition layer 33 can be determined in combination with the positions of the orthographic projections of the photosensitive device 32 and the light-emitting device 31 on the substrate 10.

In some embodiments, as shown in FIG. 1 or FIG. 7, the photosensitive device 32 includes a first charge generation layer, and a third electrode 321 and a fourth electrode 325 located on the two sides of the first charge generation layer, the third electrode 321 is located on the side of the first charge generation layer close to the driving layer 20, and is connected to the fingerprint recognition circuit 22, and the fourth electrode 325 is located on the side of the first charge generation layer away from the driving layer 20. In this way, the finger reflected light can be collected through the first charge generation layer, and the collected light signal is converted into an electrical signal, and then the electrical signal is output through the third electrode 321, the fourth electrode 325 and the fingerprint recognition circuit 22, so as to realize the collection of the finger fingerprint, and then realize the fingerprint recognition.

As shown in FIG. 1 or FIG. 7, the first charge generation layer includes a first electron generation layer 322 and a first hole generation layer 323, so that after collecting the light reflected by the finger, the optical signal can be converted into an electrical signal including holes and electrons. As shown in FIG. 1 or FIG. 7, the first hole generation layer 323 is located on the side close to the fourth electrode 325, and the first electron generation layer 322 is located on the side close to the third electrode 321, that is, the first electron generation layer 322 is located between the first hole generation layer 323 and the substrate 10; or, the first hole generation layer 323 is located on the side close to the third electrode 321, and the first electron generation layer 322 is located on the side close to the fourth electrode 325, that is, the first hole generation layer 323 is located between the first electron generation layer 322 and the substrate 10, as long as the first electron generation layer 322 and the first hole generation layer 323 can form a zero bias or a reverse bias, the embodiment of the present disclosure is not limited to this.

For the first charge generation layer including the first electron generation layer 322 and the first hole generation layer 323, taking the material of the first electron generation layer 322 as C60 as an example, the first hole generation layer 323 made of different materials has different corresponding photoelectric conversion efficiencies.

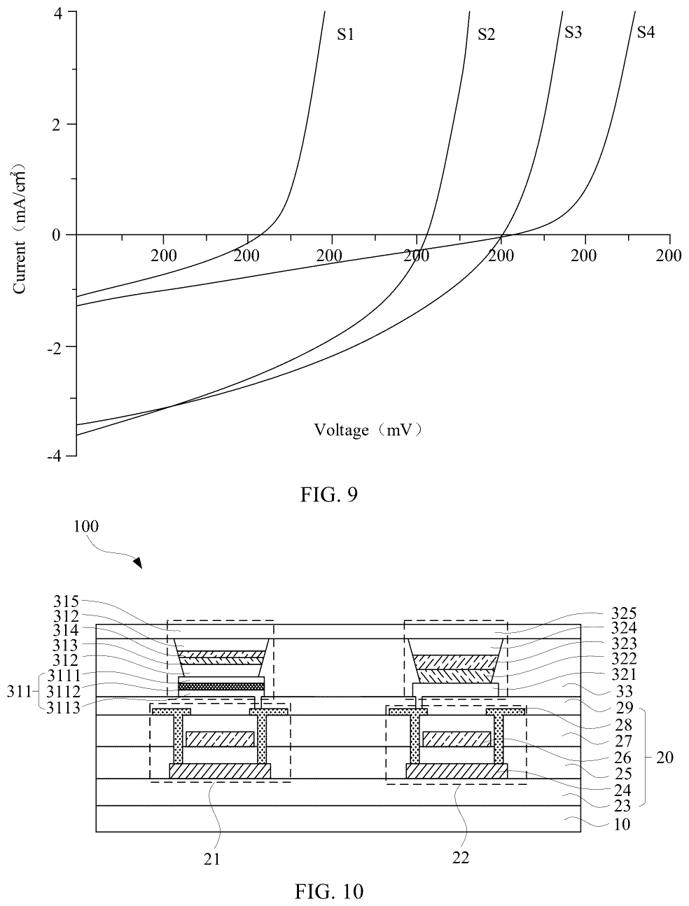

FIG. 9 shows the electrical characteristic graph S1 of the photosensitive device 32 when the material of the first electron generating layer 322 is C60 and the material of the first hole generating layer 323 is m-MTDATA, the electrical characteristic graph S2 of the photosensitive device 32 when the material of the first hole generating layer 323 is TPD, the electrical characteristic graph S3 of the photosensitive device 32 when the material of the first hole generating layer 323 is TCTA, and the electrical characteristic graph S4 of the photosensitive device 32 when the material of the first hole generating layer 323 is CBP.

Optionally, in combination with the light-emitting device 31 described above, as shown in FIG. 1 or FIG. 7, the light-emitting device 31 includes a second electron generating layer 313 and a second hole generating layer 314 located between two adjacent light-emitting functional layers 312. In this case, the second electron generating layer 313 is made on the same layer as the first electron generating layer 322, and the second hole generating layer 314 is made on the same layer as the first hole generating layer 323.

In this way, by manufacturing the second electron generating layer 313 and the first electron generating layer 322 on the same layer, and manufacturing the second hole generating layer 314 and the first hole generating layer 323 on the same layer, the manufacturing process of the photosensitive device 32 is simplified, thereby simplifying the manufacturing process of the display panel 100 and improving the manufacturing efficiency of the display panel 100.

When the first electron generating layer 322 is manufactured on the same layer as the second electron generating layer 313, and the first hole generating layer 323 is manufactured on the same layer as the second hole generating layer 314, the relative position of the first electron generating layer 322 and the first hole generating layer 323 can be specifically configured according to the number of layers of the second charge generating layer included in the light-emitting device 31, that is, according to the number of layers of the light-emitting functional layer 312 included in the light-emitting device 31.

For example, when the first hole generating layer 323 is located between the first electron generating layer 322 and the substrate 10, for the case where the light-emitting device 31 includes multiple second charge generating layers (that is, the light-emitting device 31 includes at least three light-emitting functional layers 312), the second hole generating layer 314 included in the second charge generating layer relatively close to the substrate 10 can be selected to be manufactured on the same layer as the first hole generating layer 323 of the photosensitive device 32, and the second electron generating layer 313 included in the second charge generating layer relatively far from the substrate 10 can be selected to be manufactured on the same layer as the first electron generating layer 322 of the photosensitive device 32; when the first electron generating layer 322 is located between the first hole generating layer 323 and the substrate 10, for the case where the light-emitting device 31 includes of one or more second charge generating layers (i.e., the light-emitting device 31 includes multiple light-emitting functional layers 312), the second electron generating layer 313 included in any second charge generating layer can be selected to be manufactured on the same layer as the first electron generating layer 322 of the photosensitive device 32, and the included second hole generating layer 314 can be manufactured on the same layer as the first hole generating layer 323 of the photosensitive device 32; or the second electron generating layer 313 included in the second charge generating layer relatively close to the substrate 10 can be manufactured on the same layer as the first electron generating layer 322 of the photosensitive device 32, and the second hole generating layer 314 included in the second charge generating layer relatively far from the substrate 10 can be manufactured on the same layer as the first hole generating layer 323 of the photosensitive device 32.

For example, the first electron generating layer 322 is located between the first hole generating layer 323 and the substrate 10, and the light-emitting device 31 includes two light-emitting functional layers 312 (that is, the light-emitting device includes one second charge generating layer). At this time, as shown in FIG. 7, the second charge generating layer includes a second electron generating layer 313 which is manufactured on the same layer as the first electron generating layer 322 of the photosensitive device 32, and includes a second hole generating layer 314 which is manufactured on the same layer as the first hole generating layer 323 of the photosensitive device 32.

In some embodiments, in combination with the light-emitting device 31 and the photosensitive device 32 described above, for the first electrode 311 and the second electrode 315 included in the light-emitting device 31, and the third electrode 321 and the fourth electrode 325 included in the photosensitive device 32, the first electrode 311 of the light-emitting device 31 and the third electrode 321 of the photosensitive device 32 can be manufactured on the same layer, or the second electrode 315 of the light-emitting device 31 and the fourth electrode 325 of the photosensitive device 32 can be manufactured on the same layer, alternatively, the first electrode 311 of the light-emitting device 31 and the third electrode 321 of the photosensitive device 32 can be manufactured on the same layer, and the second electrode 315 of the light-emitting device 31 and the fourth electrode 325 of the photosensitive device 32 can be manufactured on the same layer. In this way, the manufacturing process of the photosensitive device 32 can be further simplified, thereby simplifying the manufacturing process of the display panel 100 and improving the manufacturing efficiency of the display panel 100.

Taking the example that the first electrode 311 of the light-emitting device 31 and the third electrode 321 of the photosensitive device 32 are manufactured in the same layer, combined with the above case that the first electrode 311 of the light-emitting device 31 is a multi-layer structure, the third electrode 321 of the photosensitive device 32 is described in detail.

Optionally, as shown in FIG. 10, the first electrode 311 of the light-emitting device 31 includes a first transparent electrode 3111, a first reflective electrode 3112, and a second transparent electrode 3113 stacked in sequence in a direction away from the driving layer 20, and the third electrode 321 is made in the same layer as the first reflective electrode 3112. That is, the third electrode 321 is made in the same layer as a part of the film layer of the first electrode 311, and the third electrode 321 is a reflective electrode. In this way, when the first charge generation layer collects the reflected light of the finger, it can avoid the situation where light is collected on the side of the first charge generation layer close to the third electrode 321, thereby reducing the interference and improving the accuracy of fingerprint recognition.

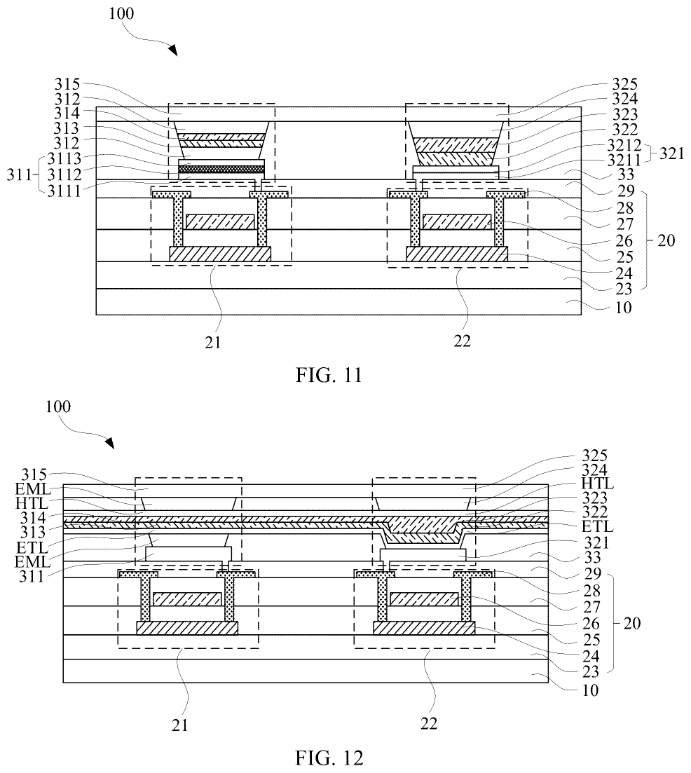

Optionally, as shown in FIG. 11, the first electrode 311 includes a first transparent electrode 3111, a first reflective electrode 3112, and a second transparent electrode 3113 stacked in sequence in a direction away from the driving layer 20, and the third electrode 321 includes a third transparent electrode 3211 and a second reflective electrode 3212 stacked in sequence in a direction away from the driving layer 20, and the third transparent electrode 3211 is made in the same layer as the first transparent electrode 3111, and the second reflective electrode 3212 is made in the same layer as the first reflective electrode 3112. That is, the third electrode 321 is made in the same layer as part of the film layer of the first electrode 311. In this way, by using the third electrode 321 including the third transparent electrode 3211 and the second reflective electrode 3212, it is possible to avoid the situation where light is collected on the side of the first charge generation layer close to the third electrode 321, reduce the situation where interference is caused, and at the same time improve the transmission efficiency of the current signal converted by the first charge generation layer.

In some embodiments, the photosensitive device 32 includes a first hole transport layer HTL and/or a first electron transport layer ETL, and the light-emitting functional layer 312 of the light-emitting device 31 includes a second hole transport layer HTL and a second electron transport layer ETL; the second hole transport layer HTL is made on the same layer as the first hole transport layer HTL, and the second electron transport layer ETL is made on the same layer as the first electron transport layer ETL.

In this way, by providing the first hole transport layer HTL and the first electron transport layer ETL, the transmission effect of the holes and electrons converted by the first charge generating layer can be better guaranteed, thereby improving the conversion effect of the photosensitive device 32 to improve the accuracy of fingerprint recognition.

For example, as shown in FIG. 12, the photosensitive device 32 includes the first hole transport layer HTL and the first electron transport layer ETL, the second hole transport layer HTL of the light-emitting device 31 is made on the same layer as the first hole transport layer HTL, and the second electron transport layer ETL is made on the same layer as the first electron transport layer ETL.

In some embodiments, the photosensitive device 32 includes an anode modification layer 324 and/or a cathode modification layer, the anode modification layer 324 is located on the side of the first hole generating layer 323 away from the first electron generating layer 322, and the cathode modification layer is located on the side of the first electron generating layer 322 away from the first hole generating layer 323.

In this way, by providing the anode modification layer 324 and/or the cathode modification layer, the transmission effect of the holes and electrons converted by the first charge generating layer can be better guaranteed, thereby improving the conversion effect of the photosensitive device 32 to improve the accuracy of fingerprint recognition.

The material of the anode modification layer 324 may be: MoO3, WO3, V2O5, etc.

For example, as shown in FIG. 12, the photosensitive device 32 includes an anode modification layer 324, and the anode modification layer 324 is located on a side of the first hole generating layer 323 away from the first electron generating layer 322.

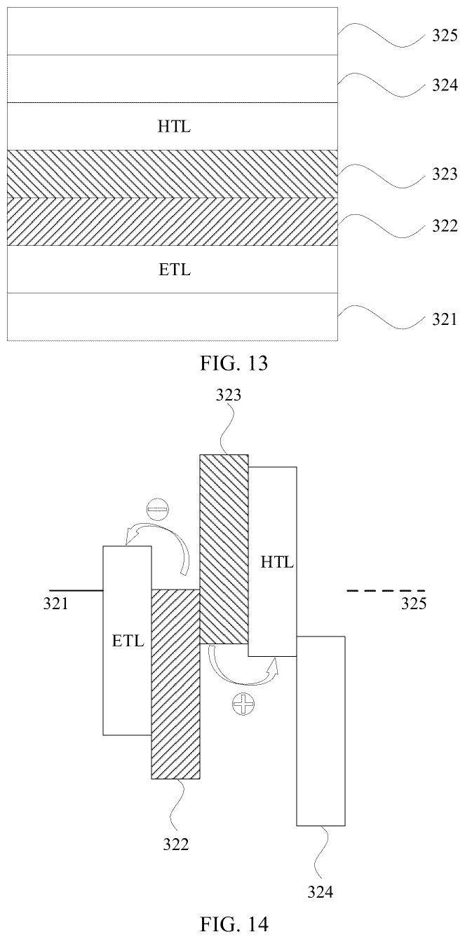

In some embodiments, as shown in FIG. 13, the photosensitive device 32 includes a third electrode 321, an electron transport layer ETL, a first electron generation layer 322, a first hole generation layer 323, a hole transport layer HTL, an anode modification layer 324, and a fourth electrode 325 which are sequentially distributed in a direction away from the driving layer 20. In this case, the energy level structure diagram of the photosensitive device 32 is shown in FIG. 14.

In the implementation of the present disclosure, the fingerprint recognition circuit 22 may include an electrode connection line, and of course may also include a thin film transistor as shown in FIG. 1 or FIG. 7. In the case of a thin film transistor, the source or drain of the thin film transistor is connected to the photosensitive device 32. That is, in combination with the above-mentioned photosensitive device 32, the source or drain of the thin film transistor is connected to the third electrode of the photosensitive device 32.

When the fingerprint recognition circuit 22 includes the electrode connection line, the electrode electrical connection line can be made in the same layer as the source and drain layer of the driving layer 20, or in the same layer as other conductive layers of the driving layer 20, and the present disclosure does not limit this. At this time, the first charge generation layer included in the photosensitive device 32 can be in a zero bias state. When fingerprint recognition is performed, when the first charge generation layer receives a light signal, it will cause the potential of the first charge generation layer in the zero bias state to change, and because the light intensity reflected by the valley and ridge of the finger is different, the change amount of the potential is also different. At this time, the electrical signal converted by the photosensitive device 32 can be directly transmitted along the electrode connection line, and the fingerprint pattern of the finger is obtained according to the different electrical signals received.

When the fingerprint recognition circuit 22 includes a thin film transistor, the fabrication of the thin film transistor can refer to the fabrication of the thin film transistor in the pixel circuit 21, and the disclosed embodiment does not limit this. At this time, when the photosensitive device 32 performs fingerprint recognition, the thin film transistor is turned on, and a certain voltage is pre-loaded on the third electrode 321 of the photosensitive device 32 through the thin film transistor, so that the thin film transistor is disconnected after the first charge generation layer included in the photosensitive device 32 is in a reverse bias state. After that, the light reflected by the valley and ridge of the finger will cause the high potential of the first charge generation layer in the reverse bias state to decrease, and because the light intensity reflected by the valley and ridge of the finger is different, the amount of potential reduction is also different. After that, the thin film transistor is turned on again, and the electrical signal output through the source or drain of the thin film transistor is different, and then the fingerprint pattern of the finger can be obtained according to the different electrical signals received.

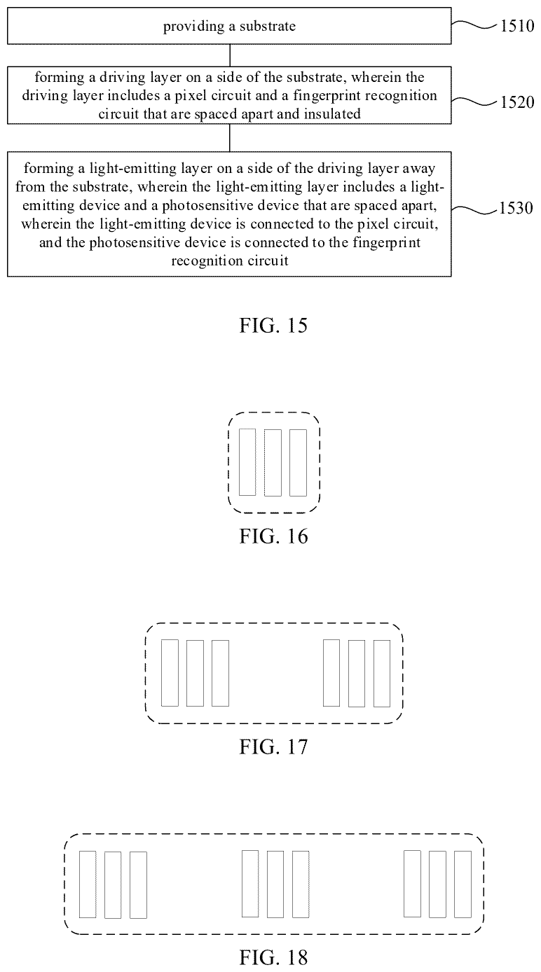

The present disclosure also provides a method for manufacturing a display panel. As shown in FIG. 15, the method includes the following steps S1510 to S1530.
Step S1510, providing a substrate;
Step S1520: forming a driving layer on a side of the substrate, wherein the driving layer includes a pixel circuit and a fingerprint recognition circuit that are spaced apart and insulated;
Step S1530: forming a light-emitting layer on a side of the driving layer away from the substrate, wherein the light-emitting layer includes a light-emitting device and a photosensitive device that are spaced apart, wherein the light-emitting device is connected to the pixel circuit, and the photosensitive device is connected to the fingerprint recognition circuit;
wherein, the photosensitive device includes a first electron generating layer and a first hole generating layer, the light-emitting device includes a plurality of stacked light-emitting functional layers, and a second electron generating layer and a second hole generating layer located between two adjacent light-emitting functional layers, one second electron generating layer is made on the same layer as the first electron generating layer, and one second hole generating layer is made on the same layer as the first hole generating layer.

In the implementation of the present disclosure, by providing the photosensitive device in the light-emitting layer to minimize the distance between the photosensitive device and the finger during fingerprint recognition, the fingerprint recognition efficiency is thereby effectively improved. In addition, by manufacturing one second electron generating layer and the first electron generating layer on the same layer, and manufacturing one second hole generating layer and the first hole generating layer on the same layer, the manufacturing process of the photosensitive device is simplified, thereby simplifying the manufacturing process of the display panel and improving the manufacturing efficiency of the display panel.

In the above step S1520, the fingerprint recognition circuit can have an electrode connection line or a thin film transistor. Taking the fingerprint recognition circuit including the electrode connection line as an example, in the process of making the driving layer, the difference from the related art is that: with reference to an orthographic projection position of the photosensitive device on the driving layer, in the process of making the conductive layer (source and drain layer) of the driving layer, forming the electrode connection line in the same layer at the orthographic projection position; taking the fingerprint recognition circuit including the thin film transistor as an example, in the process of making the driving layer, the difference from the related art is that: with reference to an orthographic projection position of the photosensitive device on the driving layer, when making the pixel circuit of the driving layer, the thin film transistor included in the fingerprint recognition circuit is formed simultaneously at the positive projection position. The related technology for making electrode connection lines or thin film transistors can refer to the related technology.

In the above step S1530, when forming the light-emitting layer on the side of the driving layer away from the substrate, it includes: forming a first electrode and a third electrode that are spaced and insulated on the side of the driving layer away from the substrate, the first electrode is an electrode of the light-emitting device, and the third electrode is an electrode of the photosensitive device; evaporating multiple light-emitting functional layers on the side of the first electrode away from the substrate, and a second electron generating layer and a second hole generating layer are sequentially stacked between two adjacent light-emitting functional layers, and at the same time, a first electron generating layer that is the same layer as a second electron generating layer and a first hole generating layer that is the same layer as a second hole generating layer are sequentially formed on the side of the third electrode away from the substrate; forming a second electrode covering the multiple light-emitting functional layers, and forming a fourth electrode covering the first hole generating layer, the second electrode is another electrode of the light-emitting device, and the fourth electrode is another electrode of the photosensitive device.

When forming the first electrode and the third electrode on the side of the driving layer away from the substrate, it can be formed by referring to the relevant technology with reference to the film structure of the first electrode and the third electrode described above. The specific process of forming multiple light-emitting functional layers, the second electron generating layer, and the second hole generating layer on the side of the first electrode away from the substrate, and forming the first electron generating layer and the first hole generating layer on the side of the third electrode away from the substrate at the same time as forming the second electron generating layer and the second hole generating layer can refer to the relevant technology, and the embodiments of the present disclosure are not limited to this.

In the above step S1530, forming the fourth electrode covering the first hole generating layer including: forming an anode modification layer on the side of the first hole generating layer away from the substrate; and forming the fourth electrode on the side of the anode modification layer away from the substrate. That is, the side of the fourth electrode close to the substrate further has an anode modification layer, so that the anode modification layer can better ensure the transmission effect of the holes and electrons converted by the first charge generating layer, thereby improving the conversion effect of the photosensitive device.

Next, in combination with the film structure of the light-emitting device shown in FIG. 5 and the photosensitive device shown in FIG. 13, the manufacturing process thereof is explained in detail.
Step 1, evaporating a first hole injection layer on a side of the first electrode away from the substrate;
Step 2, evaporating a first hole transport layer on a side of the first hole injection layer away from the substrate;
Step 3, evaporating a first blue light electron blocking layer on the side of the first hole transport layer in the first part away from the substrate;
Step 4, evaporating a first green light electron blocking layer on the side of the first hole transport layer in the second part away from the substrate;
Step 5, evaporating a first red light electron blocking layer on the side of the first hole transport layer in the third part away from the substrate;
Step 6, evaporating a first blue composite light-emitting layer on the side of the first blue light electron blocking layer away from the substrate;
Step 7, evaporating a first green composite light-emitting layer on a side of the first green light electron blocking layer away from the substrate;
Step 8, evaporating a first red composite light-emitting layer on a side of the first red light electron blocking layer away from the substrate;
Step 9, evaporating a first hole blocking layer on the sides of the first blue composite light-emitting layer, the first green composite light-emitting layer, and the first red composite light-emitting layer away from the substrate;
Step 10, evaporating a first electron transport layer on the first hole blocking layer and the side of the third electrode away from the substrate;
Step 11, evaporating an electron generation layer on a side of the first electron transport layer away from the substrate;
Step 12, evaporating a hole generating layer on the side of the electron generating layer away from the substrate;
Step 13, evaporating a second hole transport layer on the side of the hole generating layer away from the substrate;
Step 14, evaporating a second blue light electron blocking layer on a side of the first portion of the second hole transport layer away from the substrate;
Step 15, evaporating a second green light electron blocking layer on the side of the second hole transport layer in the second part away from the substrate;
Step 16, evaporating a second red light electron blocking layer on the side of the second hole transport layer in the third part away from the substrate;
Step 17, evaporating a second blue composite light-emitting layer on the side of the second blue light electron blocking layer away from the substrate;
Step 18, evaporating a second green composite light-emitting layer on the side of the second green light electron blocking layer away from the substrate;
Step 19, evaporating a second red composite light-emitting layer on the side of the second red light electron blocking layer away from the substrate;
Step 20, evaporating a second hole blocking layer on the sides of the second blue composite light-emitting layer, the second green composite light-emitting layer, and the second red composite light-emitting layer 2 away from the substrate;
Step 21, evaporating a second electron transport layer on the side of the second hole blocking layer away from the substrate;
Step 22, evaporating an anode modification layer on the side of the first electron transport layer (the electron transport layer on the side of the third electrode away from the substrate) away from the substrate;
Step 23, evaporating a cathode layer (including a second electrode and a fourth electrode) on the side of the second electron transport layer and the anode modification layer away from the substrate.

The mask plate used in the evaporation in each step can refer to the design layout of each film layer, and the material of each film layer can refer to the above description.

Example 1, step 1, evaporating, using a CFM, a mixed film layer with the material of NPB and PD as the first hole injection layer on the side of the first electrode away from the substrate, the film thickness of the first hole injection layer is 100 Å, and the deposition rate of NPB is 1 Å/s, and the deposition rate of PD is 0.03 Å/s;
Step 2: evaporating, using a CFM, a film layer with the material of NPB as the first hole transport layer on the side of the first hole injection layer away from the substrate, the film thickness of the first hole transport layer is 100 Å, and the deposition rate of NPB is 1 Å/s;
Step 3, evaporating, using an FMM, a film layer with the material of TAPC as the first blue light electron blocking layer on the side of the first part of the first hole transport layer away from the substrate, the film thickness of the first blue light electron blocking layer is 100 Å, and the deposition rate of TAPC is 1 Å/s;
Step 4: evaporating, using an FMM, a film layer with the material of TCTA as the first green light electron blocking layer on the side of the second part of the first hole transport layer away from the substrate, the film thickness of the first green light electron blocking layer is 150 Å, and the deposition rate of TCTA is 1 Å/s;
Step 5: evaporating, using an FMM, a film layer with the material of TCTA as the first red light electron blocking layer on the side of the third part of the first hole transport layer away from the substrate, the film thickness of the first red light electron blocking layer is 150 Å, and the deposition rate of TCTA is 1 Å/s;
Step 6: evaporating, using an FMM, a mixed film layer with the material of MAND and DPVBi as the first blue composite light-emitting layer on the side of the first blue light electron blocking layer away from the substrate, the film thickness of the first blue composite light-emitting layer is 150 Å, and the deposition rate of MAND is 1 Å/s, and the deposition rate of DPVBi is 0.03 Å/s;
Step 7: evaporating, using an FMM, a mixed film layer with the material of CBP and Ir(ppy)3 as the first green composite light-emitting layer on the side of the first green light electron blocking layer away from the substrate, the film thickness of the first green composite light-emitting layer is 350 Å, and the deposition rate of CBP is 1 Å/s, and the deposition rate of Ir(ppy)3 is 0.08 Å/s.
Step 8: evaporating, using an FMM, a mixed film layer with the material of TCTA and Ir(MDQ)2acac as the first red composite light-emitting layer on the side of the first red light electron blocking layer away from the substrate, the film thickness of the first red composite light-emitting layer is 600 Å, and the deposition rate of TCTA is 1 Å/s, and the deposition rate of Ir(MDQ)2acac is 0.03 Å/s.
Step 9, evaporating, using a CFM, a film layer with the material of BCP as the first hole blocking layer on the sides of the first blue composite light-emitting layer, the first green composite light-emitting layer, and the first red composite light-emitting layer away from the substrate, the film thickness of the first hole blocking layer is 50 Å, and the deposition rate of BCP is 1 Å/s;
Step 10: evaporating, using an open mask, a mixed film layer with the material of Bphen and Liq as the first electron transport layer on the side of the first hole blocking layer and the third electrode away from the substrate, the film thickness of the first electron transport layer is 200 Å, and the deposition rate of Bphen is 0.5 Å/s, and the deposition rate of Liq is 0.5 Å/s;
Step 11: evaporating, using an open mask, a film layer with the material of C60 as the electron generation layer on the side of the first electron transport layer away from the substrate, the film thickness of the electron generation layer is 200 Å, and the deposition rate of C60 is 1 Å/s;
Step 12: evaporating, using an open mask, a film layer with the material of CuPc as the hole generation layer on the side of the electron generation layer away from the substrate, the thickness of the film layer of the hole generation layer is 100 Å, and the deposition rate of CuPc is 1 Å/s;
Step 13: evaporating, using an open mask, a film layer with the material of NPB as the second hole transport layer on the side of the hole generation layer away from the substrate, the film thickness of the second hole transport layer is 300 Å, and the deposition rate of NPB is 1 Å/s;
Step 14, evaporating, using an FMM, a film layer with the material of TAPC as the second blue light electron blocking layer on the side of the first part of the second hole transport layer away from the substrate, the film thickness of the second blue light electron blocking layer is 100 Å, and the deposition rate of TAPC is 1 Å/s;
Step 15, evaporating, using an FMM, a film layer with the material of TCTA as the second green light electron blocking layer on the side of the second part of the second hole transport layer away from the substrate, the film thickness of the second green light electron blocking layer is 150 Å, and the deposition rate of TCTA is 1 Å/s;
Step 16: evaporating, using an FMM, a film layer with the material of TCTA as the second red light electron blocking layer on the side of the third part of the second hole transport layer away from the substrate, the film thickness of the second red light electron blocking layer is 150 Å, and the deposition rate of TCTA is 1 Å/s;
Step 17, evaporating, using an FMM, a mixed film layer with the material of MAND and DPVBi as the second blue composite light-emitting layer on the side of the second blue light electron blocking layer away from the substrate, the film thickness of the second blue composite light-emitting layer is 150 Å, and the deposition rate of MAND is 1 Å/s, and the deposition rate of DPVBi is 0.03 Å/s;
Step 18, evaporating, using an FMM, a mixed film layer with the material of CBP and Ir(ppy)3 as the second green composite light-emitting layer on the side of the second green light electron blocking layer away from the substrate, the film thickness of the second green composite light-emitting layer is 350 Å, and the deposition rate of CBP is 1 Å/s, and the deposition rate of Ir(ppy)3 is 0.08 Å/s;
Step 19, evaporating, using an FMM, a mixed film layer with the material of TCTA and Ir(MDQ)2acac as the second red composite light-emitting layer on the side of the second red light electron blocking layer away from the substrate, the film thickness of the second red composite light-emitting layer is 600 Å, and the deposition rate of TCTA is 1 Å/s, and the deposition rate of Ir(MDQ)2acac is 0.03 Å/s;
Step 20, evaporating, using a CFM, a film layer with the material of BCP as the second hole blocking layer on the sides of the second blue composite light-emitting layer, the second green composite light-emitting layer, and the second red composite light-emitting layer away from the substrate, the film thickness of the second hole blocking layer is 50 Å, and the deposition rate of BCP is 1 Å/s;
Step 21, evaporating, using an open mask, a mixed film layer with the material of Bphen and Liq as the second electron transport layer on the side of the second hole blocking layer away from the substrate, the film thickness of the second electron transport layer is 200 Å, and the deposition rate of Bphen is 0.5 Å/s, and the deposition rate of Liq is 0.5 Å/s;
Step 22, evaporating, using the FMM of the fingerprint recognition area, a film layer with the material of MoO3 as the anode modification layer on the side of the first electron transport layer (the electron transport layer on the side of the third electrode away from the substrate) away from the substrate, the film thickness of the anode modification layer is 15 Å, and the deposition rate of MoO3 is 0.5 Å/s;
Step 23: evaporating, using an open mask, a film layer with the material of MgAg as the cathode layer (including the second electrode and the fourth electrode) on the side of the second electron transport layer and the anode modification layer away from the substrate, and the film thickness of the cathode layer is 150 Å.

Example 2, step 1, evaporating, using a CFM, a mixed film layer with the material of NPB and PD as the first hole injection layer on the side of the first electrode away from the substrate, the film thickness of the first hole injection layer is 100 Å, and the deposition rate of NPB is 1 Å/s, and the deposition rate of PD is 0.03 Å/s;
Step 2: evaporating, using a CFM, a film layer with the material of NPB as the first hole transport layer on the side of the first hole injection layer away from the substrate, the film thickness of the first hole transport layer is 100 Å, and the deposition rate of NPB is 1 Å/s;
Step 3, evaporating, using an FMM, a film layer with the material of TAPC as the first blue light electron blocking layer on the side of the first part of the first hole transport layer away from the substrate, the film thickness of the first blue light electron blocking layer is 100 Å, and the deposition rate of TAPC is 1 Å/s;
Step 4: evaporating, using an FMM, a film layer with the material of TCTA as the first green light electron blocking layer on the side of the second part of the first hole transport layer away from the substrate, the film thickness of the first green light electron blocking layer is 150 Å, and the deposition rate of TCTA is 1 Å/s;
Step 5: evaporating, using an FMM, a film layer with the material of TCTA as the first red light electron blocking layer on the side of the third part of the first hole transport layer away from the substrate, the film thickness of the first red light electron blocking layer is 150 Å, and the deposition rate of TCTA is 1 Å/s;
Step 6: evaporating, using an FMM, a mixed film layer with the material of MAND and DPVBi as the first blue composite light-emitting layer on the side of the first blue light electron blocking layer away from the substrate, the film thickness of the first blue composite light-emitting layer is 150 Å, and the deposition rate of MAND is 1 Å/s, and the deposition rate of DPVBi is 0.03 Å/s;
Step 7: evaporating, using an FMM, a mixed film layer with the material of CBP and Ir(ppy)3 as the first green composite light-emitting layer on the side of the first green light electron blocking layer away from the substrate, the film thickness of the first green composite light-emitting layer is 350 Å, and the deposition rate of CBP is 1 Å/s, and the deposition rate of Ir(ppy)3 is 0.08 Å/s.
Step 8: evaporating, using an FMM, a mixed film layer with the material of TCTA and Ir(MDQ)2acac as the first red composite light-emitting layer on the side of the first red light electron blocking layer away from the substrate, the film thickness of the first red composite light-emitting layer is 600 Å, and the deposition rate of TCTA is 1 Å/s, and the deposition rate of Ir(MDQ)2acac is 0.03 Å/s.
Step 9, evaporating, using a CFM, a film layer with the material of BCP as the first hole blocking layer on the sides of the first blue composite light-emitting layer, the first green composite light-emitting layer, and the first red composite light-emitting layer away from the substrate, the film thickness of the first hole blocking layer is 50 Å, and the deposition rate of BCP is 1 Å/s;
Step 10: evaporating, using an open mask, a mixed film layer with the material of Bphen and Liq as the first electron transport layer on the side of the first hole blocking layer and the third electrode away from the substrate, the film thickness of the first electron transport layer is 200 Å, and the deposition rate of Bphen is 0.5 Å/s, and the deposition rate of Liq is 0.5 Å/s;
Step 11: evaporating, using an open mask, a film layer with the material of C60 as the electron generation layer on the side of the first electron transport layer away from the substrate, the film thickness of the electron generation layer is 200 Å, and the deposition rate of C60 is 1 Å/s;
Step 12: evaporating, using an open mask, a film layer with the material of m-MTDATA as the hole generation layer on the side of the electron generation layer away from the substrate, the thickness of the film layer of the hole generation layer is 100 Å, and the deposition rate of m-MTDATA is 1 Å/s;
Step 13: evaporating, using an open mask, a film layer with the material of NPB as the second hole transport layer on the side of the hole generation layer away from the substrate, the film thickness of the second hole transport layer is 300 Å, and the deposition rate of NPB is 1 Å/s;
Step 14, evaporating, using an FMM, a film layer with the material of TAPC as the second blue light electron blocking layer on the side of the first part of the second hole transport layer away from the substrate, the film thickness of the second blue light electron blocking layer is 100 Å, and the deposition rate of TAPC is 1 Å/s;
Step 15, evaporating, using an FMM, a film layer with the material of TCTA as the second green light electron blocking layer on the side of the second part of the second hole transport layer away from the substrate, the film thickness of the second green light electron blocking layer is 150 Å, and the deposition rate of TCTA is 1 Å/s;
Step 16: evaporating, using an FMM, a film layer with the material of TCTA as the second red light electron blocking layer on the side of the third part of the second hole transport layer away from the substrate, the film thickness of the second red light electron blocking layer is 150 Å, and the deposition rate of TCTA is 1 Å/s;
Step 17, evaporating, using an FMM, a mixed film layer with the material of MAND and DPVBi as the second blue composite light-emitting layer on the side of the second blue light electron blocking layer away from the substrate, the film thickness of the second blue composite light-emitting layer is 150 Å, and the deposition rate of MAND is 1 Å/s, and the deposition rate of DPVBi is 0.03 Å/s;
Step 18, evaporating, using an FMM, a mixed film layer with the material of CBP and Ir(ppy)3 as the second green composite light-emitting layer on the side of the second green light electron blocking layer away from the substrate, the film thickness of the second green composite light-emitting layer is 350 Å, and the deposition rate of CBP is 1 Å/s, and the deposition rate of Ir(ppy)3 is 0.08 Å/s;
Step 19, evaporating, using an FMM, a mixed film layer with the material of TCTA and Ir(MDQ)2acac as the second red composite light-emitting layer on the side of the second red light electron blocking layer away from the substrate, the film thickness of the second red composite light-emitting layer is 600 Å, and the deposition rate of TCTA is 1 Å/s, and the deposition rate of Ir(MDQ)2acac is 0.03 Å/s;
Step 20, evaporating, using a CFM, a film layer with the material of BCP as the second hole blocking layer on the sides of the second blue composite light-emitting layer, the second green composite light-emitting layer, and the second red composite light-emitting layer away from the substrate, the film thickness of the second hole blocking layer is 50 Å, and the deposition rate of BCP is 1 Å/s;
Step 21, evaporating, using an open mask, a mixed film layer with the material of Bphen and Liq as the second electron transport layer on the side of the second hole blocking layer away from the substrate, the film thickness of the second electron transport layer is 200 Å, and the deposition rate of Bphen is 0.5 Å/s, and the deposition rate of Liq is 0.5 Å/s;
Step 22, evaporating, using the FMM of the fingerprint recognition area, a film layer with the material of MoO3 as the anode modification layer on the side of the first electron transport layer (the electron transport layer on the side of the third electrode away from the substrate) away from the substrate, the film thickness of the anode modification layer is 15 Å, and the deposition rate of MoO3 is 0.5 Å/s;
Step 23: evaporating, using an open mask, a film layer with the material of MgAg as the cathode layer (including the second electrode and the fourth electrode) on the side of the second electron transport layer and the anode modification layer away from the substrate, and the film thickness of the cathode layer is 150 Å.

Example 3, step 1, evaporating, using a CFM, a mixed film layer with the material of NPB and PD as the first hole injection layer on the side of the first electrode away from the substrate, the film thickness of the first hole injection layer is 100 Å, and the deposition rate of NPB is 1 Å/s, and the deposition rate of PD is 0.03 Å/s;
Step 2: evaporating, using a CFM, a film layer with the material of NPB as the first hole transport layer on the side of the first hole injection layer away from the substrate, the film thickness of the first hole transport layer is 100 Å, and the deposition rate of NPB is 1 Å/s;
Step 3, evaporating, using an FMM, a film layer with the material of TAPC as the first blue light electron blocking layer on the side of the first part of the first hole transport layer away from the substrate, the film thickness of the first blue light electron blocking layer is 100 Å, and the deposition rate of TAPC is 1 Å/s;
Step 4: evaporating, using an FMM, a film layer with the material of TCTA as the first green light electron blocking layer on the side of the second part of the first hole transport layer away from the substrate, the film thickness of the first green light electron blocking layer is 150 Å, and the deposition rate of TCTA is 1 Å/s;
Step 5: evaporating, using an FMM, a film layer with the material of TCTA as the first red light electron blocking layer on the side of the third part of the first hole transport layer away from the substrate, the film thickness of the first red light electron blocking layer is 150 Å, and the deposition rate of TCTA is 1 Å/s;
Step 6: evaporating, using an FMM, a mixed film layer with the material of MAND and DPVBi as the first blue composite light-emitting layer on the side of the first blue light electron blocking layer away from the substrate, the film thickness of the first blue composite light-emitting layer is 150 Å, and the deposition rate of MAND is 1 Å/s, and the deposition rate of DPVBi is 0.03 Å/s;
Step 7: evaporating, using an FMM, a mixed film layer with the material of CBP and Ir(ppy)3 as the first green composite light-emitting layer on the side of the first green light electron blocking layer away from the substrate, the film thickness of the first green composite light-emitting layer is 350 Å, and the deposition rate of CBP is 1 Å/s, and the deposition rate of Ir(ppy)3 is 0.08 Å/s.
Step 8: evaporating, using an FMM, a mixed film layer with the material of TCTA and Ir(MDQ)2acac as the first red composite light-emitting layer on the side of the first red light electron blocking layer away from the substrate, the film thickness of the first red composite light-emitting layer is 600 Å, and the deposition rate of TCTA is 1 Å/s, and the deposition rate of Ir(MDQ)2acac is 0.03 Å/s.
Step 9, evaporating, using a CFM, a film layer with the material of BCP as the first hole blocking layer on the sides of the first blue composite light-emitting layer, the first green composite light-emitting layer, and the first red composite light-emitting layer away from the substrate, the film thickness of the first hole blocking layer is 50 Å, and the deposition rate of BCP is 1 Å/s;
Step 10: evaporating, using an open mask, a mixed film layer with the material of Bphen and Liq as the first electron transport layer on the side of the first hole blocking layer and the third electrode away from the substrate, the film thickness of the first electron transport layer is 200 Å, and the deposition rate of Bphen is 0.5 Å/s, and the deposition rate of Liq is 0.5 Å/s;
Step 11: evaporating, using an open mask, a film layer with the material of C60 as the electron generation layer on the side of the first electron transport layer away from the substrate, the film thickness of the electron generation layer is 200 Å, and the deposition rate of C60 is 1 Å/s;
Step 12: evaporating, using an open mask, a film layer with the material of Pentance as the hole generation layer on the side of the electron generation layer away from the substrate, the thickness of the film layer of the hole generation layer is 100 Å, and the deposition rate of Pentance is 1 Å/s;
Step 13: evaporating, using an open mask, a film layer with the material of NPB as the second hole transport layer on the side of the hole generation layer away from the substrate, the film thickness of the second hole transport layer is 300 Å, and the deposition rate of NPB is 1 Å/s;
Step 14, evaporating, using an FMM, a film layer with the material of TAPC as the second blue light electron blocking layer on the side of the first part of the second hole transport layer away from the substrate, the film thickness of the second blue light electron blocking layer is 100 Å, and the deposition rate of TAPC is 1 Å/s;
Step 15, evaporating, using an FMM, a film layer with the material of TCTA as the second green light electron blocking layer on the side of the second part of the second hole transport layer away from the substrate, the film thickness of the second green light electron blocking layer is 150 Å, and the deposition rate of TCTA is 1 Å/s;
Step 16: evaporating, using an FMM, a film layer with the material of TCTA as the second red light electron blocking layer on the side of the third part of the second hole transport layer away from the substrate, the film thickness of the second red light electron blocking layer is 150 Å, and the deposition rate of TCTA is 1 Å/s;
Step 17, evaporating, using an FMM, a mixed film layer with the material of MAND and DPVBi as the second blue composite light-emitting layer on the side of the second blue light electron blocking layer away from the substrate, the film thickness of the second blue composite light-emitting layer is 150 Å, and the deposition rate of MAND is 1 Å/s, and the deposition rate of DPVBi is 0.03 Å/s;
Step 18, evaporating, using an FMM, a mixed film layer with the material of CBP and Ir(ppy)3 as the second green composite light-emitting layer on the side of the second green light electron blocking layer away from the substrate, the film thickness of the second green composite light-emitting layer is 350 Å, and the deposition rate of CBP is 1 Å/s, and the deposition rate of Ir(ppy)3 is 0.08 Å/s;
Step 19, evaporating, using an FMM, a mixed film layer with the material of TCTA and Ir(MDQ)2acac as the second red composite light-emitting layer on the side of the second red light electron blocking layer away from the substrate, the film thickness of the second red composite light-emitting layer is 600 Å, and the deposition rate of TCTA is 1 Å/s, and the deposition rate of Ir(MDQ)2acac is 0.03 Å/s;
Step 20, evaporating, using a CFM, a film layer with the material of BCP as the second hole blocking layer on the sides of the second blue composite light-emitting layer, the second green composite light-emitting layer, and the second red composite light-emitting layer away from the substrate, the film thickness of the second hole blocking layer is 50 Å, and the deposition rate of BCP is 1 Å/s;
Step 21, evaporating, using an open mask, a mixed film layer with the material of Bphen and Liq as the second electron transport layer on the side of the second hole blocking layer away from the substrate, the film thickness of the second electron transport layer is 200 Å, and the deposition rate of Bphen is 0.5 Å/s, and the deposition rate of Liq is 0.5 Å/s;
Step 22, evaporating, using the FMM of the fingerprint recognition area, a film layer with the material of MoO3 as the anode modification layer on the side of the first electron transport layer (the electron transport layer on the side of the third electrode away from the substrate) away from the substrate, the film thickness of the anode modification layer is 15 Å, and the deposition rate of MoO3 is 0.5 Å/s;
Step 23: evaporating, using an open mask, a film layer with the material of MgAg as the cathode layer (including the second electrode and the fourth electrode) on the side of the second electron transport layer and the anode modification layer away from the substrate, and the film thickness of the cathode layer is 150 Å.

Example 4, step 1, evaporating, using a CFM, a mixed film layer with the material of NPB and PD as the first hole injection layer on the side of the first electrode away from the substrate, the film thickness of the first hole injection layer is 100 Å, and the deposition rate of NPB is 1 Å/s, and the deposition rate of PD is 0.03 Å/s;
Step 2: evaporating, using a CFM, a film layer with the material of NPB as the first hole transport layer on the side of the first hole injection layer away from the substrate, the film thickness of the first hole transport layer is 100 Å, and the deposition rate of NPB is 1 Å/s;
Step 3, evaporating, using an FMM, a film layer with the material of TAPC as the first blue light electron blocking layer on the side of the first part of the first hole transport layer away from the substrate, the film thickness of the first blue light electron blocking layer is 100 Å, and the deposition rate of TAPC is 1 Å/s;
Step 4: evaporating, using an FMM, a film layer with the material of TCTA as the first green light electron blocking layer on the side of the second part of the first hole transport layer away from the substrate, the film thickness of the first green light electron blocking layer is 150 Å, and the deposition rate of TCTA is 1 Å/s;
Step 5: evaporating, using an FMM, a film layer with the material of TCTA as the first red light electron blocking layer on the side of the third part of the first hole transport layer away from the substrate, the film thickness of the first red light electron blocking layer is 150 Å, and the deposition rate of TCTA is 1 Å/s;
Step 6: evaporating, using an FMM, a mixed film layer with the material of MAND and DPVBi as the first blue composite light-emitting layer on the side of the first blue light electron blocking layer away from the substrate, the film thickness of the first blue composite light-emitting layer is 150 Å, and the deposition rate of MAND is 1 Å/s, and the deposition rate of DPVBi is 0.03 Å/s;
Step 7: evaporating, using an FMM, a mixed film layer with the material of CBP and Ir(ppy)3 as the first green composite light-emitting layer on the side of the first green light electron blocking layer away from the substrate, the film thickness of the first green composite light-emitting layer is 350 Å, and the deposition rate of CBP is 1 Å/s, and the deposition rate of Ir(ppy)3 is 0.08 Å/s.
Step 8: evaporating, using an FMM, a mixed film layer with the material of TCTA and Ir(MDQ)2acac as the first red composite light-emitting layer on the side of the first red light electron blocking layer away from the substrate, the film thickness of the first red composite light-emitting layer is 600 Å, and the deposition rate of TCTA is 1 Å/s, and the deposition rate of Ir(MDQ)2acac is 0.03 Å/s.
Step 9, evaporating, using a CFM, a film layer with the material of BCP as the first hole blocking layer on the sides of the first blue composite light-emitting layer, the first green composite light-emitting layer, and the first red composite light-emitting layer away from the substrate, the film thickness of the first hole blocking layer is 50 Å, and the deposition rate of BCP is 1 Å/s;
Step 10: evaporating, using an open mask, a mixed film layer with the material of Bphen and Liq as the first electron transport layer on the side of the first hole blocking layer and the third electrode away from the substrate, the film thickness of the first electron transport layer is 200 Å, and the deposition rate of Bphen is 0.5 Å/s, and the deposition rate of Liq is 0.5 Å/s;
Step 11: evaporating, using an open mask, a film layer with the material of C60 as the electron generation layer on the side of the first electron transport layer away from the substrate, the film thickness of the electron generation layer is 200 Å, and the deposition rate of C60 is 1 Å/s;
Step 12: evaporating, using an open mask, a film layer with the material of SubPc as the hole generation layer on the side of the electron generation layer away from the substrate, the thickness of the film layer of the hole generation layer is 100 Å, and the deposition rate of SubPc is 1 Å/s;
Step 13: evaporating, using an open mask, a film layer with the material of NPB as the second hole transport layer on the side of the hole generation layer away from the substrate, the film thickness of the second hole transport layer is 300 Å, and the deposition rate of NPB is 1 Å/s;
Step 14, evaporating, using an FMM, a film layer with the material of TAPC as the second blue light electron blocking layer on the side of the first part of the second hole transport layer away from the substrate, the film thickness of the second blue light electron blocking layer is 100 Å, and the deposition rate of TAPC is 1 Å/s;
Step 15, evaporating, using an FMM, a film layer with the material of TCTA as the second green light electron blocking layer on the side of the second part of the second hole transport layer away from the substrate, the film thickness of the second green light electron blocking layer is 150 Å, and the deposition rate of TCTA is 1 Å/s;
Step 16: evaporating, using an FMM, a film layer with the material of TCTA as the second red light electron blocking layer on the side of the third part of the second hole transport layer away from the substrate, the film thickness of the second red light electron blocking layer is 150 Å, and the deposition rate of TCTA is 1 Å/s;
Step 17, evaporating, using an FMM, a mixed film layer with the material of MAND and DPVBi as the second blue composite light-emitting layer on the side of the second blue light electron blocking layer away from the substrate, the film thickness of the second blue composite light-emitting layer is 150 Å, and the deposition rate of MAND is 1 Å/s, and the deposition rate of DPVBi is 0.03 Å/s;
Step 18, evaporating, using an FMM, a mixed film layer with the material of CBP and Ir(ppy)3 as the second green composite light-emitting layer on the side of the second green light electron blocking layer away from the substrate, the film thickness of the second green composite light-emitting layer is 350 Å, and the deposition rate of CBP is 1 Å/s, and the deposition rate of Ir(ppy)3 is 0.08 Å/s;
Step 19, evaporating, using an FMM, a mixed film layer with the material of TCTA and Ir(MDQ)2acac as the second red composite light-emitting layer on the side of the second red light electron blocking layer away from the substrate, the film thickness of the second red composite light-emitting layer is 600 Å, and the deposition rate of TCTA is 1 Å/s, and the deposition rate of Ir(MDQ)2acac is 0.03 Å/s;
Step 20, evaporating, using a CFM, a film layer with the material of BCP as the second hole blocking layer on the sides of the second blue composite light-emitting layer, the second green composite light-emitting layer, and the second red composite light-emitting layer away from the substrate, the film thickness of the second hole blocking layer is 50 Å, and the deposition rate of BCP is 1 Å/s;
Step 21, evaporating, using an open mask, a mixed film layer with the material of Bphen and Liq as the second electron transport layer on the side of the second hole blocking layer away from the substrate, the film thickness of the second electron transport layer is 200 Å, and the deposition rate of Bphen is 0.5 Å/s, and the deposition rate of Liq is 0.5 Å/s;
Step 22, evaporating, using the FMM of the fingerprint recognition area, a film layer with the material of MoO3 as the anode modification layer on the side of the first electron transport layer (the electron transport layer on the side of the third electrode away from the substrate) away from the substrate, the film thickness of the anode modification layer is 15 Å, and the deposition rate of MoO3 is 0.5 Å/s;
Step 23: evaporating, using an open mask, a film layer with the material of MgAg as the cathode layer (including the second electrode and the fourth electrode) on the side of the second electron transport layer and the anode modification layer away from the substrate, and the film thickness of the cathode layer is 150 Å.

Example 5, step 1, evaporating, using a CFM, a mixed film layer with the material of NPB and PD as the first hole injection layer on the side of the first electrode away from the substrate, the film thickness of the first hole injection layer is 100 Å, and the deposition rate of NPB is 1 Å/s, and the deposition rate of PD is 0.03 Å/s;
Step 2: evaporating, using a CFM, a film layer with the material of NPB as the first hole transport layer on the side of the first hole injection layer away from the substrate, the film thickness of the first hole transport layer is 100 Å, and the deposition rate of NPB is 1 Å/s;
Step 3, evaporating, using an FMM, a film layer with the material of TAPC as the first blue light electron blocking layer on the side of the first part of the first hole transport layer away from the substrate, the film thickness of the first blue light electron blocking layer is 100 Å, and the deposition rate of TAPC is 1 Å/s;
Step 4: evaporating, using an FMM, a film layer with the material of TCTA as the first green light electron blocking layer on the side of the second part of the first hole transport layer away from the substrate, the film thickness of the first green light electron blocking layer is 150 Å, and the deposition rate of TCTA is 1 Å/s;
Step 5: evaporating, using an FMM, a film layer with the material of TCTA as the first red light electron blocking layer on the side of the third part of the first hole transport layer away from the substrate, the film thickness of the first red light electron blocking layer is 150 Å, and the deposition rate of TCTA is 1 Å/s;
Step 6: evaporating, using an FMM, a mixed film layer with the material of MAND and DPVBi as the first blue composite light-emitting layer on the side of the first blue light electron blocking layer away from the substrate, the film thickness of the first blue composite light-emitting layer is 150 Å, and the deposition rate of MAND is 1 Å/s, and the deposition rate of DPVBi is 0.03 Å/s;
Step 7: evaporating, using an FMM, a mixed film layer with the material of CBP and Ir(ppy)3 as the first green composite light-emitting layer on the side of the first green light electron blocking layer away from the substrate, the film thickness of the first green composite light-emitting layer is 350 Å, and the deposition rate of CBP is 1 Å/s, and the deposition rate of Ir(ppy)3 is 0.08 Å/s.
Step 8: evaporating, using an FMM, a mixed film layer with the material of TCTA and Ir(MDQ)2acac as the first red composite light-emitting layer on the side of the first red light electron blocking layer away from the substrate, the film thickness of the first red composite light-emitting layer is 600 Å, and the deposition rate of TCTA is 1 Å/s, and the deposition rate of Ir(MDQ)2acac is 0.03 Å/s.
Step 9, evaporating, using a CFM, a film layer with the material of BCP as the first hole blocking layer on the sides of the first blue composite light-emitting layer, the first green composite light-emitting layer, and the first red composite light-emitting layer away from the substrate, the film thickness of the first hole blocking layer is 50 Å, and the deposition rate of BCP is 1 Å/s;
Step 10: evaporating, using an open mask, a mixed film layer with the material of Bphen and Liq as the first electron transport layer on the side of the first hole blocking layer and the third electrode away from the substrate, the film thickness of the first electron transport layer is 200 Å, and the deposition rate of Bphen is 0.5 Å/s, and the deposition rate of Liq is 0.5 Å/s;
Step 11: evaporating, using an open mask, a film layer with the material of C60 as the electron generation layer on the side of the first electron transport layer away from the substrate, the film thickness of the electron generation layer is 200 Å, and the deposition rate of C60 is 1 Å/s;
Step 12: evaporating, using an open mask, a film layer with the material of CuPc as the hole generation layer on the side of the electron generation layer away from the substrate, the thickness of the film layer of the hole generation layer is 100 Å, and the deposition rate of CuPc is 1 Å/s;
Step 13: evaporating, using an open mask, a film layer with the material of NPB as the second hole transport layer on the side of the hole generation layer away from the substrate, the film thickness of the second hole transport layer is 300 Å, and the deposition rate of NPB is 1 Å/s;
Step 14, evaporating, using an FMM, a film layer with the material of TAPC as the second blue light electron blocking layer on the side of the first part of the second hole transport layer away from the substrate, the film thickness of the second blue light electron blocking layer is 100 Å, and the deposition rate of TAPC is 1 Å/s;
Step 15, evaporating, using an FMM, a film layer with the material of TCTA as the second green light electron blocking layer on the side of the second part of the second hole transport layer away from the substrate, the film thickness of the second green light electron blocking layer is 150 Å, and the deposition rate of TCTA is 1 Å/s;
Step 16: evaporating, using an FMM, a film layer with the material of TCTA as the second red light electron blocking layer on the side of the third part of the second hole transport layer away from the substrate, the film thickness of the second red light electron blocking layer is 150 Å, and the deposition rate of TCTA is 1 Å/s;
Step 17, evaporating, using an FMM, a mixed film layer with the material of MAND and DPVBi as the second blue composite light-emitting layer on the side of the second blue light electron blocking layer away from the substrate, the film thickness of the second blue composite light-emitting layer is 150 Å, and the deposition rate of MAND is 1 Å/s, and the deposition rate of DPVBi is 0.03 Å/s;
Step 18, evaporating, using an FMM, a mixed film layer with the material of CBP and Ir(ppy)3 as the second green composite light-emitting layer on the side of the second green light electron blocking layer away from the substrate, the film thickness of the second green composite light-emitting layer is 350 Å, and the deposition rate of CBP is 1 Å/s, and the deposition rate of Ir(ppy)3 is 0.08 Å/s;
Step 19, evaporating, using an FMM, a mixed film layer with the material of TCTA and Ir(MDQ)2acac as the second red composite light-emitting layer on the side of the second red light electron blocking layer away from the substrate, the film thickness of the second red composite light-emitting layer is 600 Å, and the deposition rate of TCTA is 1 Å/s, and the deposition rate of Ir(MDQ)2acac is 0.03 Å/s;
Step 20, evaporating, using a CFM, a film layer with the material of BCP as the second hole blocking layer on the sides of the second blue composite light-emitting layer, the second green composite light-emitting layer, and the second red composite light-emitting layer away from the substrate, the film thickness of the second hole blocking layer is 50 Å, and the deposition rate of BCP is 1 Å/s;
Step 21, evaporating, using an open mask, a mixed film layer with the material of Bphen and Liq as the second electron transport layer on the side of the second hole blocking layer away from the substrate, the film thickness of the second electron transport layer is 200 Å, and the deposition rate of Bphen is 0.5 Å/s, and the deposition rate of Liq is 0.5 Å/s;
Step 22, evaporating, using the FMM of the fingerprint recognition area, a film layer with the material of WO3 as the anode modification layer on the side of the first electron transport layer (the electron transport layer on the side of the third electrode away from the substrate) away from the substrate, the film thickness of the anode modification layer is 15 Å, and the deposition rate of WO3 is 0.5 Å/s;
Step 23: evaporating, using an open mask, a film layer with the material of MgAg as the cathode layer (including the second electrode and the fourth electrode) on the side of the second electron transport layer and the anode modification layer away from the substrate, and the film thickness of the cathode layer is 150 Å.

Example 6, step 1, evaporating, using a CFM, a mixed film layer with the material of NPB and PD as the first hole injection layer on the side of the first electrode away from the substrate, the film thickness of the first hole injection layer is 100 Å, and the deposition rate of NPB is 1 Å/s, and the deposition rate of PD is 0.03 Å/s;
Step 2: evaporating, using a CFM, a film layer with the material of NPB as the first hole transport layer on the side of the first hole injection layer away from the substrate, the film thickness of the first hole transport layer is 100 Å, and the deposition rate of NPB is 1 Å/s;
Step 3, evaporating, using an FMM, a film layer with the material of TAPC as the first blue light electron blocking layer on the side of the first part of the first hole transport layer away from the substrate, the film thickness of the first blue light electron blocking layer is 100 Å, and the deposition rate of TAPC is 1 Å/s;
Step 4: evaporating, using an FMM, a film layer with the material of TCTA as the first green light electron blocking layer on the side of the second part of the first hole transport layer away from the substrate, the film thickness of the first green light electron blocking layer is 150 Å, and the deposition rate of TCTA is 1 Å/s;
Step 5: evaporating, using an FMM, a film layer with the material of TCTA as the first red light electron blocking layer on the side of the third part of the first hole transport layer away from the substrate, the film thickness of the first red light electron blocking layer is 150 Å, and the deposition rate of TCTA is 1 Å/s;
Step 6: evaporating, using an FMM, a mixed film layer with the material of MAND and DPVBi as the first blue composite light-emitting layer on the side of the first blue light electron blocking layer away from the substrate, the film thickness of the first blue composite light-emitting layer is 150 Å, and the deposition rate of MAND is 1 Å/s, and the deposition rate of DPVBi is 0.03 Å/s;
Step 7: evaporating, using an FMM, a mixed film layer with the material of CBP and Ir(ppy)3 as the first green composite light-emitting layer on the side of the first green light electron blocking layer away from the substrate, the film thickness of the first green composite light-emitting layer is 350 Å, and the deposition rate of CBP is 1 Å/s, and the deposition rate of Ir(ppy)3 is 0.08 Å/s.
Step 8: evaporating, using an FMM, a mixed film layer with the material of TCTA and Ir(MDQ)2acac as the first red composite light-emitting layer on the side of the first red light electron blocking layer away from the substrate, the film thickness of the first red composite light-emitting layer is 600 Å, and the deposition rate of TCTA is 1 Å/s, and the deposition rate of Ir(MDQ)2acac is 0.03 Å/s.
Step 9, evaporating, using a CFM, a film layer with the material of BCP as the first hole blocking layer on the sides of the first blue composite light-emitting layer, the first green composite light-emitting layer, and the first red composite light-emitting layer away from the substrate, the film thickness of the first hole blocking layer is 50 Å, and the deposition rate of BCP is 1 Å/s;
Step 10: evaporating, using an open mask, a mixed film layer with the material of Bphen and Liq as the first electron transport layer on the side of the first hole blocking layer and the third electrode away from the substrate, the film thickness of the first electron transport layer is 200 Å, and the deposition rate of Bphen is 0.5 Å/s, and the deposition rate of Liq is 0.5 Å/s;
Step 11: evaporating, using an open mask, a film layer with the material of C60 as the electron generation layer on the side of the first electron transport layer away from the substrate, the film thickness of the electron generation layer is 200 Å, and the deposition rate of C60 is 1 Å/s;
Step 12: evaporating, using an open mask, a film layer with the material of CuPc as the hole generation layer on the side of the electron generation layer away from the substrate, the thickness of the film layer of the hole generation layer is 100 Å, and the deposition rate of CuPc is 1 Å/s;
Step 13: evaporating, using an open mask, a film layer with the material of NPB as the second hole transport layer on the side of the hole generation layer away from the substrate, the film thickness of the second hole transport layer is 300 Å, and the deposition rate of NPB is 1 Å/s;
Step 14, evaporating, using an FMM, a film layer with the material of TAPC as the second blue light electron blocking layer on the side of the first part of the second hole transport layer away from the substrate, the film thickness of the second blue light electron blocking layer is 100 Å, and the deposition rate of TAPC is 1 Å/s;
Step 15, evaporating, using an FMM, a film layer with the material of TCTA as the second green light electron blocking layer on the side of the second part of the second hole transport layer away from the substrate, the film thickness of the second green light electron blocking layer is 150 Å, and the deposition rate of TCTA is 1 Å/s;
Step 16: evaporating, using an FMM, a film layer with the material of TCTA as the second red light electron blocking layer on the side of the third part of the second hole transport layer away from the substrate, the film thickness of the second red light electron blocking layer is 150 Å, and the deposition rate of TCTA is 1 Å/s;
Step 17, evaporating, using an FMM, a mixed film layer with the material of MAND and DPVBi as the second blue composite light-emitting layer on the side of the second blue light electron blocking layer away from the substrate, the film thickness of the second blue composite light-emitting layer is 150 Å, and the deposition rate of MAND is 1 Å/s, and the deposition rate of DPVBi is 0.03 Å/s;
Step 18, evaporating, using an FMM, a mixed film layer with the material of CBP and Ir(ppy)3 as the second green composite light-emitting layer on the side of the second green light electron blocking layer away from the substrate, the film thickness of the second green composite light-emitting layer is 350 Å, and the deposition rate of CBP is 1 Å/s, and the deposition rate of Ir(ppy)3 is 0.08 Å/s;
Step 19, evaporating, using an FMM, a mixed film layer with the material of TCTA and Ir(MDQ)2acac as the second red composite light-emitting layer on the side of the second red light electron blocking layer away from the substrate, the film thickness of the second red composite light-emitting layer is 600 Å, and the deposition rate of TCTA is 1 Å/s, and the deposition rate of Ir(MDQ)2acac is 0.03 Å/s;
Step 20, evaporating, using a CFM, a film layer with the material of BCP as the second hole blocking layer on the sides of the second blue composite light-emitting layer, the second green composite light-emitting layer, and the second red composite light-emitting layer away from the substrate, the film thickness of the second hole blocking layer is 50 Å, and the deposition rate of BCP is 1 Å/s;
Step 21, evaporating, using an open mask, a mixed film layer with the material of Bphen and Liq as the second electron transport layer on the side of the second hole blocking layer away from the substrate, the film thickness of the second electron transport layer is 200 Å, and the deposition rate of Bphen is 0.5 Å/s, and the deposition rate of Liq is 0.5 Å/s;
Step 22, evaporating, using the FMM of the fingerprint recognition area, a film layer with the material of V2O5 as the anode modification layer on the side of the first electron transport layer (the electron transport layer on the side of the third electrode away from the substrate) away from the substrate, the film thickness of the anode modification layer is 15 Å, and the deposition rate of V2O5 is 0.5 Å/s;
Step 23: evaporating, using an open mask, a film layer with the material of MgAg as the cathode layer (including the second electrode and the fourth electrode) on the side of the second electron transport layer and the anode modification layer away from the substrate, and the film thickness of the cathode layer is 150 Å.

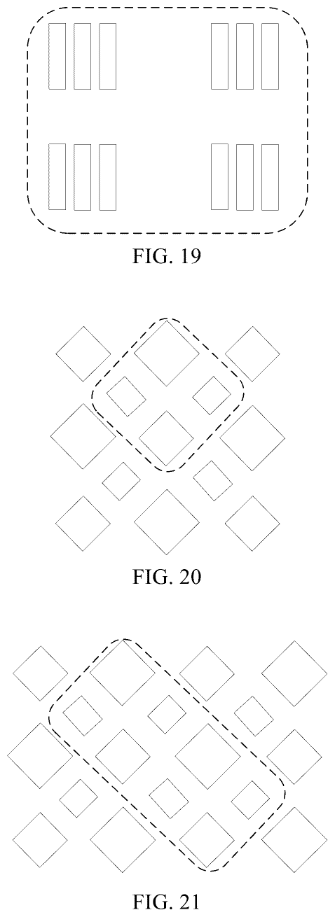

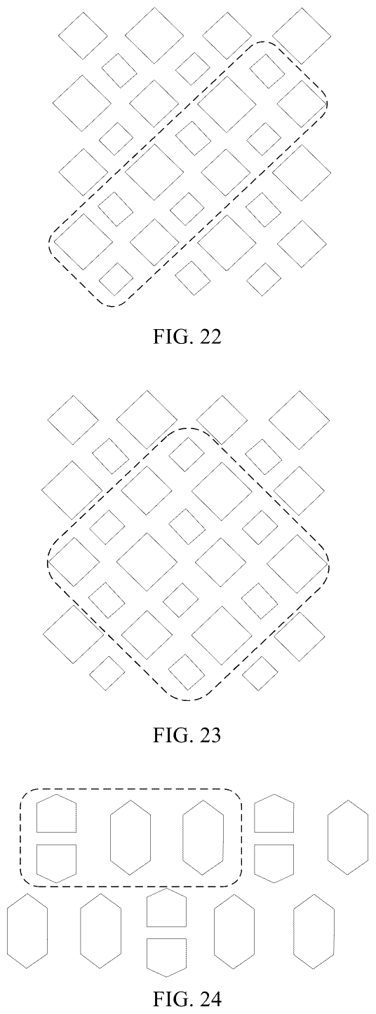

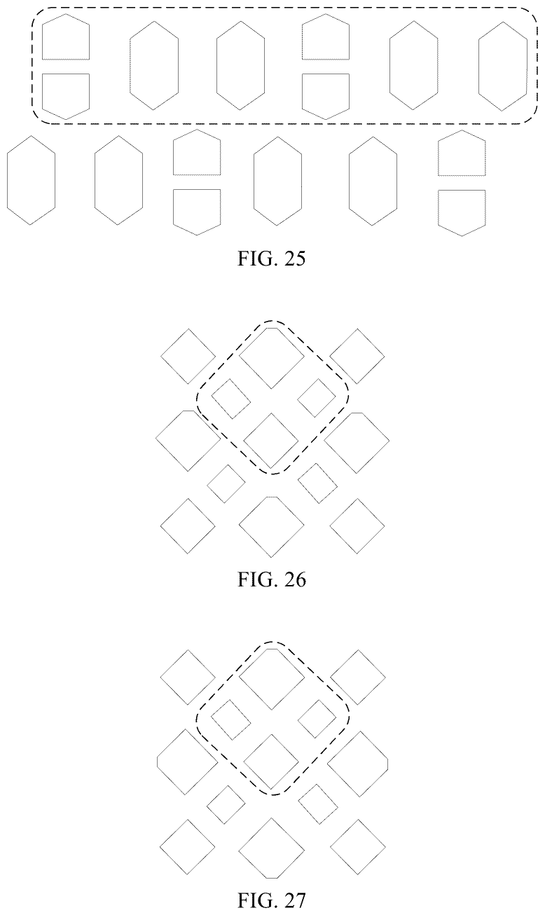

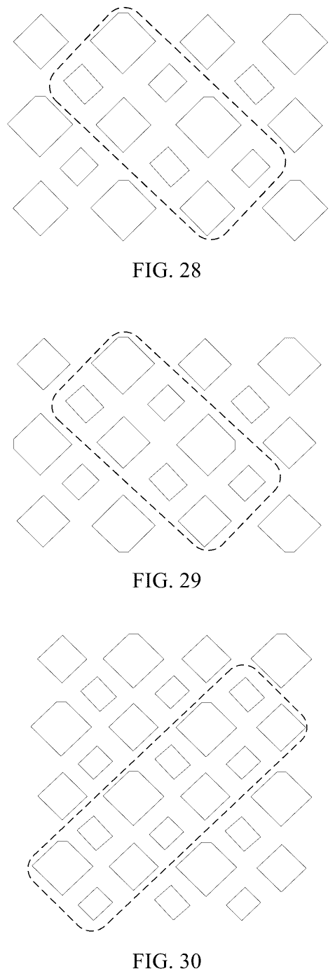

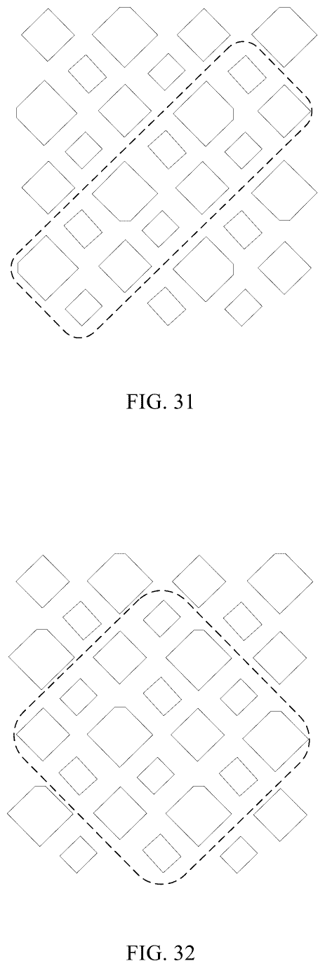

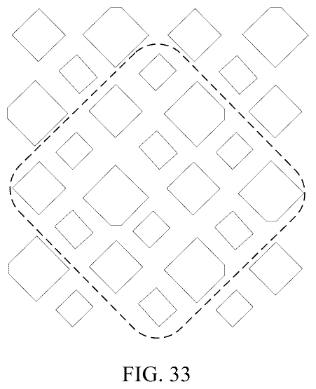

The CFM used in the above steps 1, 2, 9, 20, and 21 can be selected according to the arrangement of the light-emitting devices in the light-emitting layer. Taking the arrangement of the light-emitting devices as sRGB arrangement as an example, the openings of the CFM are shown in FIGS. 16, 17, 18, and 19; taking the arrangement of the light-emitting devices as diamond arrangement as an example, the openings of the CFM are shown in FIGS. 20, 21, 22, and 23; taking the arrangement of the light-emitting devices as GGRB arrangement as an example, the openings of the CFM are shown in FIGS. 24 and 25; taking the arrangement of the light-emitting devices as blue diamond arrangement as an example, the openings of the CFM are shown in FIGS. 26, 27, 28, 29, 30, 31, 32, and 33.

It should be noted that although the steps of the method for manufacturing a display panel in the present disclosure are described in a specific order in the accompanying drawings, this does not require or imply that the steps must be performed in this specific order, or that all the steps shown must be performed to achieve the desired results. Additionally or alternatively, some steps may be omitted, multiple steps may be combined into one step, and/or one step may be decomposed into multiple steps, etc.

The disclosed embodiment also provides a display device, which includes the display panel described in the above embodiment. Thus, for the display device including the above display panel, the fingerprint recognition function is realized while realizing the image display function, and the distance between the finger and the photosensitive device during fingerprint recognition can be shortened, so as to effectively improve the fingerprint recognition efficiency.

Those skilled in the art will readily appreciate other embodiments of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only, and the true scope and spirit of the present disclosure are indicated by the appended claims.

1. A display panel, comprising:
a substrate;
a driving layer, disposed on a side of the substrate, and comprising a pixel circuit and a fingerprint recognition circuit that are spaced apart and insulated; and
a light-emitting layer disposed on a side of the driving layer away from the substrate, and comprising a light-emitting device and a photosensitive device that are spaced apart, wherein the light-emitting device is connected to the pixel circuit, and the photosensitive device is connected to the fingerprint recognition circuit.

2. The display panel according to claim 1, wherein the photosensitive device comprises a first electron generating layer and a first hole generating layer; and
the light-emitting device comprises a plurality of stacked light-emitting functional layers, and a second electron generating layer and a second hole generating layer located between two adjacent light-emitting functional layers, wherein one of the second electron generating layer is formed on a same layer as the first electron generating layer, and one of the second hole generating layer is formed on a same layer as the first hole generating layer.

3. The display panel according to claim 2, wherein the first electron generating layer is disposed between the first hole generating layer and the substrate.

4. The display panel according to claim 2, wherein the light-emitting device comprises at least three light-emitting functional layers, and the first electron generating layer is disposed on a side of the first hole generating layer away from the substrate.

5. The display panel according to claim 2, wherein the photosensitive device comprises a first hole transport layer and/or a first electron transport layer, and the light-emitting functional layer of the light-emitting device comprises a second hole transport layer and a second electron transport layer; and
wherein one of the second hole transport layer is formed on a same layer as the first hole transport layer, and one of the second electron transport layer is formed on a same layer as the first electron transport layer.

6. The display panel according to claim 2, wherein the photosensitive device comprises an anode modification layer and/or a cathode modification layer; and
wherein the anode modification layer is disposed on a side of the first hole generating layer away from the first electron generating layer, and the cathode modification layer is disposed on a side of the first electron generating layer away from the first hole generating layer.

7. The display panel according to claim 6, wherein a material of the anode modification layer is: MoO3, WO3 or V2O5.

8. The display panel according to claim 1, wherein the light-emitting device comprises a first electrode and a second electrode, and the light sensing device comprises a third electrode and a fourth electrode; and
wherein the first electrode is connected to the pixel circuit, the third electrode is connected to the fingerprint recognition circuit, and the first electrode and the third electrode are formed in a same layer.

9. The display panel according to claim 8, wherein the first electrode comprises a first transparent electrode, a first reflective electrode, and a second transparent electrode stacked in sequence in a direction away from the driving layer, and the third electrode is formed in a same layer as the first reflective electrode.

10. The display panel according to claim 8, wherein the first electrode comprises a first transparent electrode, a first reflective electrode, and a second transparent electrode sequentially stacked in a direction away from the driving layer; and
wherein the third electrode comprises a third transparent electrode and a second reflective electrode which are sequentially stacked in a direction away from the driving layer, wherein the third transparent electrode is formed in a same layer as the first transparent electrode, and the second reflective electrode is formed in a same layer as the first reflective electrode.

11. The display panel according to claim 8, wherein the second electrode and the fourth electrode are manufactured in a same layer.

12. The display panel according to claim 1, wherein the fingerprint recognition circuit comprises a thin film transistor, and a source or a drain of the thin film transistor is connected to the photosensitive device.

13. A method for manufacturing a display panel, wherein the method comprises:
providing a substrate;
forming a driving layer on a side of the substrate, wherein the driving layer comprises a pixel circuit and a fingerprint recognition circuit that are spaced apart and insulated; and
forming a light-emitting layer on a side of the driving layer away from the substrate, wherein the light-emitting layer comprises a light-emitting device and a photosensitive device that are spaced apart, wherein the light-emitting device is connected to the pixel circuit, and the photosensitive device is connected to the fingerprint recognition circuit,
wherein the photosensitive device comprises a first electron generating layer and a first hole generating layer, the light-emitting device comprises a plurality of stacked light-emitting functional layers, and a second electron generating layer and a second hole generating layer disposed between two adjacent light-emitting functional layers, one of the second electron generating layer is formed on a same layer as the first electron generating layer, and one of the second hole generating layer is formed on a same layer as the first hole generating layer.

14. The method according to claim 13, wherein the forming the light-emitting layer on the side of the driving layer away from the substrate, comprises:
forming a first electrode and a third electrode on a side of the driving layer away from the substrate, wherein the first electrode is an electrode of the light-emitting device, and the third electrode is an electrode of the photosensitive device;
evaporating a plurality of light-emitting functional layers on a side of the first electrode away from the substrate, with a second electron generating layer and a second hole generating layer sequentially stacked between two adjacent light-emitting functional layers, and meanwhile forming sequentially a first electron generating layer in a same layer as the second electron generating layer and a first hole generating layer in a same layer as the second hole generating layer on a side of the third electrode away from the substrate; and
forming a second electrode covering the plurality of light-emitting functional layers, and forming a fourth electrode covering the first hole generating layer, wherein the second electrode is another electrode of the light-emitting device, and the fourth electrode is another electrode of the photosensitive device.

15. The method according to claim 14, wherein the forming the fourth electrode covering the first hole generating layer comprises:
forming an anode modification layer on a side of the first hole generating layer away from the substrate; and
forming the fourth electrode on a side of the anode modification layer away from the substrate.

16. A display device, wherein the display device comprises a display panel, wherein the display panel comprises:
a substrate;
a driving layer, disposed on a side of the substrate, and comprising a pixel circuit and a fingerprint recognition circuit that are spaced apart and insulated; and
a light-emitting layer disposed on a side of the driving layer away from the substrate, and comprising a light-emitting device and a photosensitive device that are spaced apart, wherein the light-emitting device is connected to the pixel circuit, and the photosensitive device is connected to the fingerprint recognition circuit.

17. The display device according to claim 16, wherein the photosensitive device comprises a first electron generating layer and a first hole generating layer; and
the light-emitting device comprises a plurality of stacked light-emitting functional layers, and a second electron generating layer and a second hole generating layer located between two adjacent light-emitting functional layers, wherein one of the second electron generating layer is formed on a same layer as the first electron generating layer, and one of the second hole generating layer is formed on a same layer as the first hole generating layer.

18. The display device according to claim 17, wherein the first electron generating layer is disposed between the first hole generating layer and the substrate.

19. The display device according to claim 17, wherein the light-emitting device comprises at least three light-emitting functional layers, and the first electron generating layer is disposed on a side of the first hole generating layer away from the substrate.

20. The display device according to claim 17, wherein the photosensitive device comprises a first hole transport layer and/or a first electron transport layer, and the light-emitting functional layer of the light-emitting device comprises a second hole transport layer and a second electron transport layer; and
wherein one of the second hole transport layer is formed on a same layer as the first hole transport layer, and one of the second electron transport layer is formed on a same layer as the first electron transport layer.
